(19) United States
(12) Patent Application Publication
(10) Pub. No.: US 2021/0368648 A1
(43) Pub. Date: Nov. 25, 2021

(54) COOLING DEVICE, CONTROL METHOD, AND STORAGE MEDIUM

(71) Applicant: NEC Corporation, Minato-ku, Tokyo (JP)

(72) Inventors: Masaki CHIBA, Tokyo (JP); Minoru YOSHIKAWA, Tokyo (JP); Hisato SAKUMA, Tokyo (JP); Takafumi NATSUMEDA, Tokyo (JP)

(73) Assignee: NEC Corporation, Minato-ku, Tokyo (JP)

(21) Appl. No.: 16/963,392

(22) PCT Filed: Jan. 21, 2019
(86) PCT No.: PCT/JP2019/001585

§ 371 Date: Jul. 20, 2020

(30) Foreign Application Priority Data
Jan. 25, 2018 (JP) 2018-010422

(51) Int. Cl. H05K 7/20

(52) U.S. Cl. CPC H05K 7/20209; H05K 7/202; H05K 7/20145

(57) ABSTRACT

To provide a cooling device capable of cooling a heat-generating body using simple configuration, the cooling device comprises two evaporators, two condensers, a compressor and an expansion valve, and is configured so that any one among a first flow path setting, a second flow path setting, a third flow path setting, and a fourth flow path setting can be selected.

### TECHNICAL FIELD

The present invention relates to a cooling device and the like, and, for example, relates to a cooling device cooling a heat-generating body such as electronic equipment by use of a coolant.

### BACKGROUND ART

In recent years, an amount of information processing is increasing with improvement in information processing technologies and development of the Internet environment. In order to process the enormous amount of information, data centers are installed and operated in a plurality of regions. Pieces of electronic equipment such as a computer and a server are installed in a server room in a data center in a concentrated manner. Consequently, energy efficiency of the data center is enhanced.

For example, heat-generating parts such as a central processing unit (CPU) and/or a large scale integration (LSI) are accommodated in electronic equipment, such as a computer or a server, in a server room in a data center installed in each region. The heat-generating parts entail heat generation. Accordingly, the electronic equipment (heat-generating body) is cooled by use of, for example, an air conditioner in the server room in the data center.

However, since an amount of information processing is increasing in a data center, power consumption of an air conditioner is also increasing. Consequently, an operating cost of a data center is also increasing. Accordingly, reduction of power consumption of an air conditioner in a server room in a data center has been requested by an administrator or the like of the data center.

PTL 1 discloses a technology of reducing power consumption of an air conditioner, as a technology for a cooling system. Specifically, the technology described in PTL 1 cools inside a server room (an air-conditioned room such as a computer room) in a data center by properly using a system circulating a coolant without use of a compressor (natural circulation cycle) and a system circulating a coolant by use of a compressor (compression refrigeration cycle).

In the natural circulation cycle, heat of electronic equipment (heat load generating spot) in a server room is radiated to outside the server room by circulating a coolant between a first evaporator provided on the electronic equipment in the server room and a first condenser provided outside the server room without use of a compressor.

In the compression refrigeration cycle, a coolant is circulated between a third evaporator provided on electronic equipment in a server room and a second condenser provided in the server room by use of a compressor, and also a coolant is circulated between a second evaporator provided in the server room and a first condenser provided outside the server room without use of a compressor. A heat exchanger is configured with the second condenser and the second evaporator, and heat exchange is performed between the second condenser and the second evaporator. Consequently, heat of the electronic equipment in the server room is radiated to outside the server room successively through the third evaporator, the second condenser, the second evaporator, and the first condenser.

In the technology described in PTL 1, when the temperature in a server room is lower than the temperature outside the server room, heat of electronic equipment in the server room is radiated to outside the server room by use of the compression refrigeration cycle. When the temperature in the server room is higher than the temperature outside the server room, heat of electronic equipment in the server room is radiated to outside the server room by use of the natural circulation cycle. In this case, when cooling capacity is insufficient, the compression refrigeration cycle is used along with the natural circulation cycle.

On the other hand, when the temperature in the server room is lower than the temperature outside the server room, heat of the electronic equipment in the server room is radiated to outside the server room by use of the compression refrigeration cycle.

In the compression refrigeration cycle, an amount of a liquid-phase coolant flowing into the second evaporator is adjusted based on the temperature of a coolant condensed by the second condenser. Specifically, as the temperature of the coolant condensed by the second condenser lowers, the amount of the liquid-phase coolant flowing into the aforementioned second evaporator is decreased. Consequently, an amount of the liquid-phase coolant caused to flow out to the third evaporator by the second condenser performing heat exchange with the second evaporator decreases, and therefore an amount of a gas-phase coolant flowing out from the third evaporator to the compressor decreases. Thus, the technology described in PTL 1 reduces power consumption.

A related technology is also described in PTL 2.

### CITATION LIST

### Patent Literature

PTL 1: Japanese Unexamined Patent Application Publication No. S64-038558

PTL 2: Japanese Patent No. 5041343

### SUMMARY OF INVENTION

### Technical Problem

As described in “Background Art,” a coolant is circulated between the first evaporator and the first condenser in the natural circulation cycle in the technology described in PTL 1. On the other hand, in the compression refrigeration cycle, a coolant is circulated between the third evaporator and the second condenser, and in addition, heat exchange is performed in the heat exchanger between the second condenser and the second evaporator, and a coolant is further circulated between the second evaporator and the first condenser.

Thus, there is a problem that the configuration of the compression refrigeration cycle includes a more number of parts compared with the configuration of the natural circulation cycle and is complex, due to inclusion of the heat exchanger including the second condenser and the second evaporator.

The present invention has been made in view of the aforementioned problem, and an object of the present invention is to provide a cooling device capable of cooling a heat-generating body with a simple configuration.

### Solution to Problem

A cooling device according to the present invention includes: a first evaporator and a second evaporator each of which receiving heat of a heat-generating body, evaporating an internally stored liquid-phase coolant by heat of the heat-generating body and causing a gas-phase coolant to flow out; a first condenser and a second condenser being connected to each of the first evaporator and the second evaporator, condensing a gas-phase coolant flowing out from each of the first evaporator and the second evaporator, and causing a liquid-phase coolant to flow out to each of the first evaporator and the second evaporator; a compressor being connected to the first evaporator, the second evaporator, the first condenser, and the second condenser, and compressing a gas-phase coolant flowing out from the first evaporator and the second evaporator; and an expansion valve being connected to the first evaporator, the second evaporator, the first condenser, and the second condenser, and expanding a liquid-phase coolant flowing out from the first condenser and the second condenser, wherein, out of a first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve, a second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve, a third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and a fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve, one of the first passage setting, the second passage setting or the third passage setting, and the fourth passage setting is provided in a selectable manner.

A control method according to the present invention includes controlling a cooling device including: a first evaporator and a second evaporator each of which receiving heat of a heat-generating body, evaporating an internally stored liquid-phase coolant by heat of the heat-generating body, and causing a gas-phase coolant to flow out; a first condenser and a second condenser being connected to each of the first evaporator and the second evaporator, condensing a gas-phase coolant flowing out from each of the first evaporator and the second evaporator, and causing a liquid-phase coolant to flow out to each of the first evaporator and the second evaporator; a compressor being connected to the first evaporator, the second evaporator, the first condenser, and the second condenser, and compressing a gas-phase coolant flowing out from the first evaporator and the second evaporator; an expansion valve being connected to the first evaporator, the second evaporator, the first condenser, and the second condenser, and expanding a liquid-phase coolant flowing out from the first condenser and the second condenser; and a control unit, wherein the control unit can select one of a first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve, a second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve, a third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and a fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve, selects one of the first passage setting, the second passage setting, the third passage setting, and the fourth passage setting, based on a first temperature being a temperature of air close to at least one of the first condenser and the second condenser, and, based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

A storage medium according to the present invention stores a control program for controlling a cooling device including: a first evaporator and a second evaporator each of which receiving heat of a heat-generating body, evaporating an internally stored liquid-phase coolant by heat of the heat-generating body, and causing a gas-phase coolant to flow out; a first condenser and a second condenser being connected to each of the first evaporator and the second evaporator, condensing a gas-phase coolant flowing out from each of the first evaporator and the second evaporator, and causing a liquid-phase coolant to flow out to each of the first evaporator and the second evaporator; a compressor being connected to the first evaporator, the second evaporator, the first condenser, and the second condenser, and compressing a gas-phase coolant flowing out from the first evaporator and the second evaporator; an expansion valve being connected to the first evaporator, the second evaporator, the first condenser, and the second condenser, and expanding a liquid-phase coolant flowing out from the first condenser and the second condenser; and a control unit, the control program causing a computer to execute processing of causing the control unit to be able to select one of a first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve, a second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve, a third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and a fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve, select one of the first passage setting, the second passage setting, the third passage setting, and the fourth passage setting, based on a first temperature being a temperature of air close to at least one of the first condenser and the second condenser, and, based on a content of a selected setting, cause a gas-phase coolant flowing out from each of the first evaporator and the second evaporator to flow into each of the first condenser and the second condenser and cause a liquid-phase coolant flowing out from each of the first condenser and the second condenser to flow into each of the first evaporator and the second evaporator.

### Advantageous Effects of Invention

A cooling device according to the present invention can cool a heat-generating body with a simple configuration.

### BRIEF DESCRIPTION OF DRAWINGS

FIG. 1 is a schematic diagram illustrating a configuration of a cooling device according to a first example embodiment of the present invention.

FIG. 2 is a schematic diagram illustrating part of the configuration.

FIG. 3 is a schematic diagram illustrating part of the configuration.

FIG. 4 is a diagram for illustrating a first passage setting.

FIG. 5 is a diagram for illustrating the first passage setting.

FIG. 6 is a diagram for illustrating a second passage setting.

FIG. 7 is a diagram for illustrating the second passage setting.

FIG. 8 is a diagram for illustrating a third passage setting.

FIG. 9 is a diagram for illustrating the third passage setting.

FIG. 10 is a diagram for illustrating a fourth passage setting.

FIG. 11 is a diagram for illustrating the fourth passage setting.

FIG. 12 is a perspective view illustrating a configuration of each of a first evaporator, a second evaporator, a first condenser, and a second condenser.

FIG. 13 is a transparent schematic diagram in which an internal configuration of each of the first evaporator, the second evaporator, the first condenser, and the second condenser is schematically seen through.

FIG. 14 is a schematic diagram illustrating a configuration of a cooling device according to a second example embodiment of the present invention.

FIG. 15 is a diagram illustrating an operation flow of the cooling device according to the second example embodiment of present invention.

FIG. 16 is a schematic diagram illustrating a configuration of a cooling device according to a third example embodiment of the present invention.

FIG. 17 is a diagram illustrating an operation flow of the cooling device according to the third example embodiment of the present invention.

### EXAMPLE EMBODIMENT

### First Example Embodiment

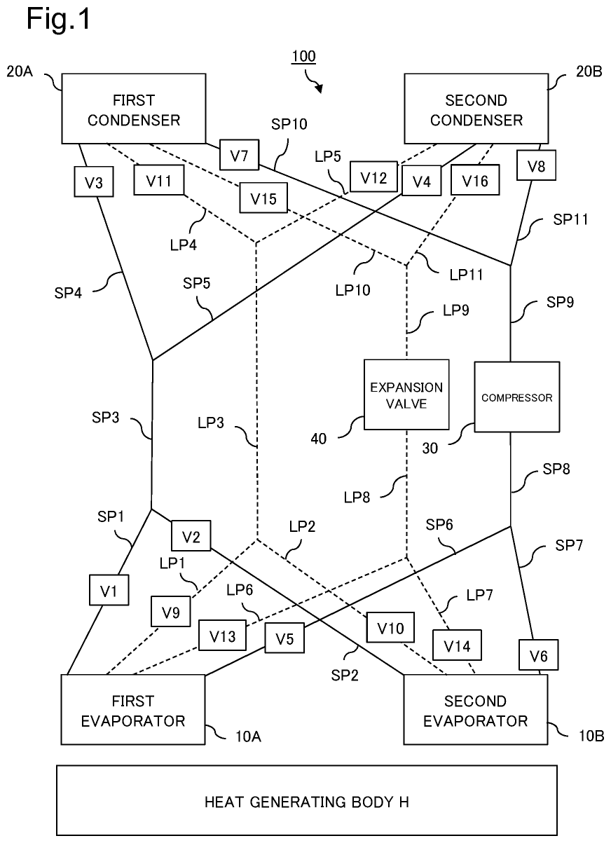

A cooling device 100 according to a first example embodiment will be described according to diagrams. FIG. 1 is a schematic diagram illustrating a configuration of the cooling device 100.

For example, the cooling device 100 cools a heat-generating body H (for example, electronic equipment such as a server or a computer) placed in a server room in a data center, by use of a coolant (hereinafter referred to as COO). For example, the coolant COO is composed of a polymer material. When reaching a boiling point due to a temperature rise, the coolant COO undergoes a phase change from a liquid-phase coolant (hereinafter referred to as LP-COO) to a gas-phase coolant (hereinafter referred to as GP-COO). When reaching the boiling point due to a temperature fall, the coolant COO undergoes a phase change from the gas-phase coolant GP-COO to the liquid-phase coolant LP-COO. For example, hydrofluorocarbon (HFC), hydrofluoroether (HFE), hydrofluoroolefin (HFO), or hydrochlorofluoroolefin (HCFO) may be used as the coolant COO. The coolant COO is contained in the cooling device 100 in a hermetically sealed state. More specifically, a liquid-phase coolant LP-COO is injected from unillustrated holes provided on a first evaporator 10A and a second evaporator 10B to be described later. Subsequently, the cooling device 100 is evacuated with all on-off valves V1 to V16 to be described later open, and the inside of the cooling device 100 is always maintained at a saturated vapor pressure of the coolant by closing the unillustrated holes provided on the first evaporator 10A and the second evaporator 10B to be described later.

A configuration of the cooling device 100 will be described. Referring to FIG. 1, the cooling device 100 includes the first evaporator 10A, the second evaporator 10B, a first condenser 20A, a second condenser 20B, a compressor 30, and an expansion valve 40. As illustrated in FIG. 1, the cooling device 100 further includes steam pipes SP1 to SP11. As illustrated in FIG. 1, the cooling device 100 further includes liquid pipes LP1 to LP11. The cooling device 100 further includes the on-off valves V1 to V16.

In the following description, when the steam pipes SP1 to SP11 do not need to be distinguished from one another, each pipe is referred to as a steam pipe SP. Further, in the following description, when the liquid pipes LP1 to LP11 do not need to be distinguished from one another, each pipe is referred to as a liquid pipe LP. Further, in the following description, when the on-off valves V1 to V16 do not need to be distinguished from one another, each valve is referred to as an on-off valve V.

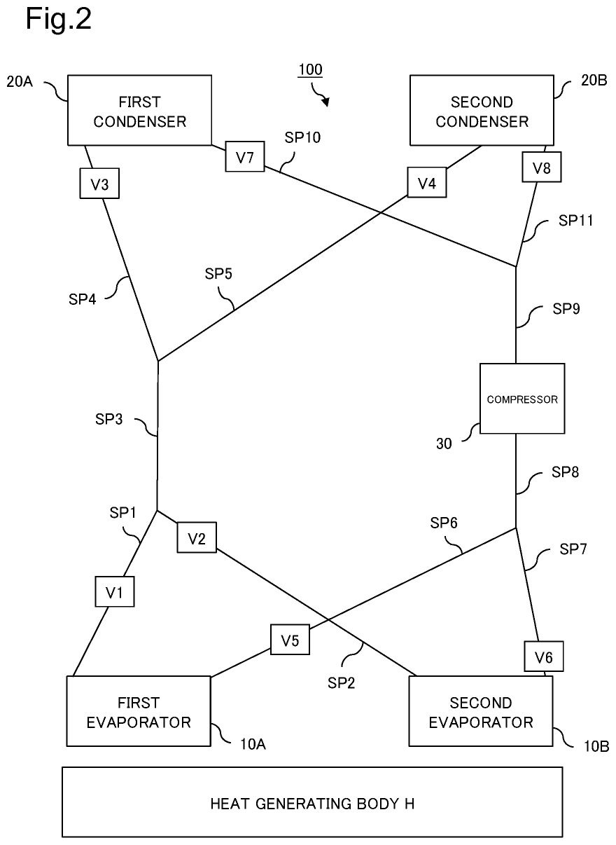

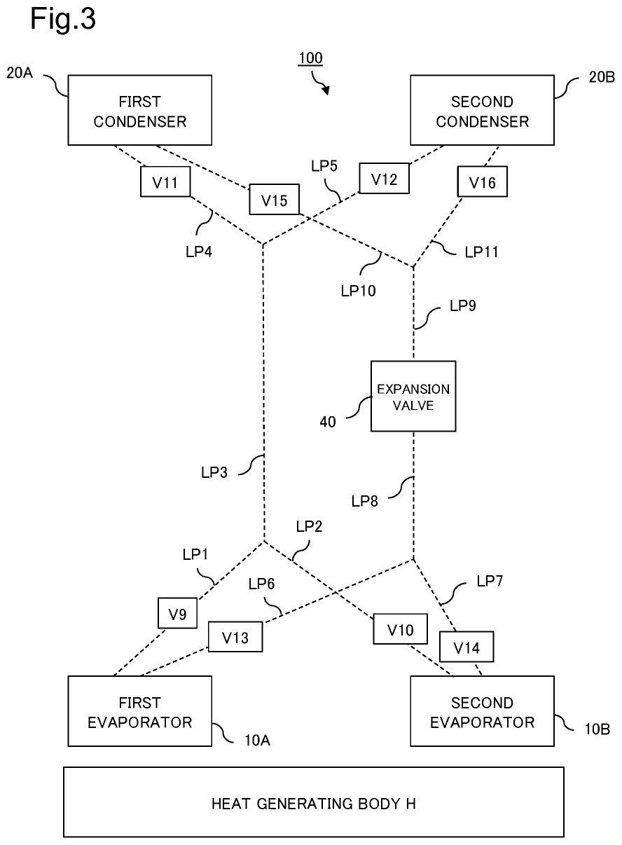

FIG. 2 is a schematic diagram illustrating part of the configuration of the cooling device 100 and illustrates passages through which a gas-phase coolant GP-COO moves from each of the first evaporator 10A and the second evaporator 10B to each of the first condenser 20A and the second condenser 20B. Specifically, FIG. 2 is a diagram acquired by removing the expansion valve 40, the liquid pipes LP1 to LP11, and the on-off valves V9 to V16 from FIG. 1. FIG. 3 is a schematic diagram illustrating part of the configuration of the cooling device 100 and illustrates passages through which a liquid-phase coolant LP-COO moves from each of the first condenser 20A and the second condenser 20B to each of the first evaporator 10A and the second evaporator 10B. Specifically, FIG. 3 is a diagram acquired by removing the compressor 30, the steam pipes SP1 to SP11, and the on-off valves V1 to V8 from FIG. 1.

The first evaporator 10A will be described. A cavity is provided inside the first evaporator 10A. A liquid-phase coolant LP-COO is stored in the cavity of the first evaporator 10A. For example, the first evaporator 10A is installed in a server room in a data center.

Referring to FIG. 1, the first evaporator 10A is provided close to the heat-generating body H. The first evaporator 10A is thermally connected to the heat-generating body H. The first evaporator 10A is connected to the first condenser 20A, the second condenser 20B, the compressor 30, and the expansion valve 40. The first evaporator 10A may or may not be in contact with the heat-generating body H as long as the first evaporator 10A is thermally connected to the heat-generating body H.

Specifically, as illustrated in FIG. 1 and FIG. 2, the first evaporator 10A is connected to the first condenser 20A through the steam pipe SP1, the steam pipe SP3, the steam pipe SP4, the on-off valve V1, and the on-off valve V3. The first evaporator 10A is further connected to the second condenser 20B through the steam pipe SP1, the steam pipe SP3, the steam pipe SP5, the on-off valve V1, and the on-off valve V4. The first evaporator 10A is further connected to the first condenser 20A through the steam pipe SP6, the steam pipe SP8, the compressor 30, the steam pipe SP9, the steam pipe SP10, the on-off valve V5, and the on-off valve V7. The first evaporator 10A is further connected to the second condenser 20B through the steam pipe SP6, the steam pipe SP8, the compressor 30, the steam pipe SP9, the steam pipe SP11, the on-off valve V5, and the on-off valve V8.

Further, as illustrated in FIG. 1 and FIG. 3, the first evaporator 10A is connected to the first condenser 20A through the liquid pipe LP1, the liquid pipe LP3, the liquid pipe LP4, the on-off valve V9, and the on-off valve V11. The first evaporator 10A is further connected to the second condenser 20B through the liquid pipe LP1, the liquid pipe LP3, the liquid pipe LP5, the on-off valve V9, and the on-off valve V12. The first evaporator 10A is further connected to the first condenser 20A through the liquid pipe LP6, the liquid pipe LP8, the expansion valve 40, the liquid pipe LP9, the liquid pipe LP10, the on-off valve V13, and the on-off valve V15. The first evaporator 10A is further connected to the second condenser 20B through the liquid pipe LP6, the liquid pipe LP8, the expansion valve 40, the liquid pipe LP9, the liquid pipe LP11, the on-off valve V13, and the on-off valve V16.

The first evaporator 10A receives heat from the heat-generating body H. The liquid-phase coolant LP-COO inside the first evaporator 10A is evaporated by the heat from the heat-generating body H. Consequently, a gas-phase coolant GP-COO is generated in the first evaporator 10A. The gas-phase coolant GP-COO generated in the first evaporator 10A flows out toward at least one of the first condenser 20A and the second condenser 20B, based on one of a first passage setting, a second passage setting, a third passage setting, and a fourth passage setting to be described later. Further, a liquid-phase coolant LP-COO flowing out from at least one of the first condenser 20A and the second condenser 20B flows into the first evaporator 10A. The first evaporator 10A has been described above.

The second evaporator 10B will be described. A cavity is provided inside the second evaporator 10B. A liquid-phase coolant LP-COO is stored in the cavity of the second evaporator 10B. For example, the second evaporator 10B is installed in a server room in a data center.

Referring to FIG. 1, the second evaporator 10B is provided close to the heat-generating body H, similarly to the first evaporator 10A. The second evaporator 10B is thermally connected to the heat-generating body H. The second evaporator 10B is connected to the first condenser 20A, the second condenser 20B, the compressor 30, and the expansion valve 40. The second evaporator 10B may or may not be in contact with the heat-generating body H as long as the second evaporator 10B is thermally connected to the heat-generating body H.

Specifically, as illustrated in FIG. 1 and FIG. 2, the second evaporator 10B is connected to the first condenser 20A through the steam pipe SP2, the steam pipe SP3, the steam pipe SP4, the on-off valve V2, and the on-off valve V3. The second evaporator 10B is further connected to the second condenser 20B through the steam pipe SP2, the steam pipe SP3, the steam pipe SP5, the on-off valve V2, and the on-off valve V4. The second evaporator 10B is further connected to the first condenser 20A through the steam pipe SP7, the steam pipe SP8, the compressor 30, the steam pipe SP9, the steam pipe SP10, the on-off valve V6, and the on-off valve V7. The second evaporator 10B is further connected to the second condenser 20B through the steam pipe SP7, the steam pipe SP8, the compressor 30, the steam pipe SP9, the steam pipe SP11, the on-off valve V6, and the on-off valve V8.

Further, as illustrated in FIG. 1 and FIG. 3, the second evaporator 10B is connected to the first condenser 20A through the liquid pipe LP2, the liquid pipe LP3, the liquid pipe LP4, the on-off valve V10, and the on-off valve V11. The second evaporator 10B is further connected to the second condenser 20B through the liquid pipe LP2, the liquid pipe LP3, the liquid pipe LP5, the on-off valve V10, and the on-off valve V12. The second evaporator 10B is further connected to the first condenser 20A through the liquid pipe LP7, the liquid pipe LP8, the expansion valve 40, the liquid pipe LP9, the liquid pipe LP10, the on-off valve V14, and the on-off valve V15. The second evaporator 10B is further connected to the second condenser 20B through the liquid pipe LP7, the liquid pipe LP8, the expansion valve 40, the liquid pipe LP9, the liquid pipe LP11, the on-off valve V14, and the on-off valve V16.

The second evaporator 10B receives heat from the heat-generating body H. The liquid-phase coolant LP-COO inside the second evaporator 10B is evaporated by the heat from the heat-generating body H. Consequently, a gas-phase coolant GP-COO is generated in the second evaporator 10B. The gas-phase coolant GP-COO generated in the second evaporator 10B flows out toward at least one of the first condenser 20A and the second condenser 20B, based on one of the first passage setting, the second passage setting, the third passage setting, and the fourth passage setting to be described later. Further, a liquid-phase coolant LP-COO flowing out from at least one of the first condenser 20A and the second condenser 20B flows into the second evaporator 10B. The second evaporator 10B has been described above.

The first condenser 20A and the second condenser 20B will be described. A cavity is provided inside each of the first condenser 20A and the second condenser 20B. Each of the first condenser 20A and the second condenser 20B is installed outside a server room (for example, outdoors).

Referring to FIG. 1 and FIG. 2, each of the first condenser 20A and the second condenser 20B is connected to each of the first evaporator 10A, the second evaporator 10B, the compressor 30, and the expansion valve 40. Specific connection relations of the first condenser 20A and the second condenser 20B are as described in the connection relations of the aforementioned first evaporator 10A and the second evaporator 10B.

Each of the first condenser 20A and the second condenser 20B radiates heat of a gas-phase coolant GP-COO to outside the cooling device 100. When the first condenser 20A and the second condenser 20B are provided outside a server room, each of the first condenser 20A and the second condenser 20B radiates heat of a gas-phase coolant GP-COO to the air outside the server room. Consequently, each of the first condenser 20A and the second condenser 20B condenses a gas-phase coolant GP-COO flowing out from at least one of the first evaporator 10A and the second evaporator 10B. Consequently, a liquid-phase coolant LP-COO is generated in each of the first condenser 20A and the second condenser 20B. The liquid-phase coolant LP-COO generated in each of the first condenser 20A and the second condenser 20B flows out to each of the first evaporator 10A and the second evaporator 10B.

The compressor 30 will be described. Referring to FIG. 1, the compressor 30 is connected to the first evaporator 10A, the second evaporator 10B, the first condenser 20A, and the second condenser 20B. Specifically, as illustrated in FIG. 1 and FIG. 2, the compressor 30 is connected to the first evaporator 10A through the steam pipe SP8, the steam pipe SP6, and the on-off valve V5. The compressor 30 is further connected to the second evaporator 10B through the steam pipe SP8, the steam pipe SP7, and the on-off valve V6. The compressor 30 is further connected to the first condenser 20A through the steam pipe SP9, the steam pipe SP10, and the on-off valve V7. The compressor 30 is further connected to the second condenser 20B through the steam pipe SP9, the steam pipe SP11, and the on-off valve V8.

The compressor 30 compresses a gas-phase coolant GP-COO flowing out from at least one of the first evaporator 10A and the second evaporator 10B. By adiabatic compression of the gas-phase coolant GP-COO by the compressor 30, the pressure of the gas-phase coolant GP-COO increases, and also the temperature of the gas-phase coolant GP-COO rises.

The expansion valve 40 will be described. Referring to FIG. 1 and FIG. 3, the expansion valve 40 is connected to the first evaporator 10A, the second evaporator 10B, the first condenser 20A, and the second condenser 20B. Specifically, as illustrated in FIG. 1 and FIG. 3, the expansion valve 40 is connected to the first evaporator 10A through the liquid pipe LP8, the liquid pipe LP6, and the on-off valve V13. The expansion valve 40 is further connected to the second evaporator 10B through the liquid pipe LP8, the liquid pipe LP7, and the on-off valve V14. The expansion valve 40 is further connected to the first condenser 20A through the liquid pipe LP9, the liquid pipe LP10, and the on-off valve V15. The expansion valve 40 is further connected to the second condenser 20B through the liquid pipe LP9, the liquid pipe LP11, and the on-off valve V16.

The expansion valve 40 expands a liquid-phase coolant LP-COO flowing out from at least one of the first condenser 20A and the second condenser 20B. By adiabatic expansion of the liquid-phase coolant LP-COO by the expansion valve 40, the pressure of the liquid-phase coolant LP-COO decreases, and also the temperature of the liquid-phase coolant LP-COO falls.

The on-off valves V1 to V16 will be described. Each of the on-off valves V1 to V16 is provided in such a way as to be able to open or close a passage of a coolant COO at each setting spot. For example, an electric control valve may be used as each of the on-off valves V1 to V16.

As illustrated in FIG. 1, the on-off valves V1 to V8 are provided on the steam pipes SP1, SP2, SP4, SP5, SP6, SP7, SP10, and SP11, respectively. While the on-off valves V1 to V8 are illustrated at positions illustrated in FIG. 1 and FIG. 2 for convenience of generation of drawings, the valves are actually provided at positions described below.

The on-off valve V1 is provided at the end of the steam pipe SP1 on the first evaporator 10A side. The on-off valve V2 is provided at the end of the steam pipe SP2 on the second evaporator 10B side. The on-off valve V3 is provided at the end of the steam pipe SP4 on the steam pipe SP3 side. The on-off valve V4 is provided at the end of the steam pipe SP5 on the steam pipe SP3 side. The on-off valve V5 is provided at the end of the steam pipe SP6 on the first evaporator 10A side. The on-off valve V6 is provided at the end of the steam pipe SP7 on the second evaporator 10B side. The on-off valve V7 is provided at the end of the steam pipe SP10 on the steam pipe SP9 side. The on-off valve V8 is provided at the end of the steam pipe SP11 on the steam pipe SP9 side.

As illustrated in FIG. 1, the on-off valves V9 to V16 are provided on the liquid pipes LP1, LP2, LP4, LP5, LP6, LP7, LP10, and LP11, respectively. While the on-off valves V9 to V16 are illustrated at positions illustrated in FIG. 1 and FIG. 3 for convenience of generation of drawings, the valves are actually provided at positions described below.

The on-off valve V9 is provided at the end of the liquid pipe LP1 on the liquid pipe LP3 side. The on-off valve V10 is provided at the end of the liquid pipe LP2 on the liquid pipe LP3 side. The on-off valve V11 is provided at the end of the liquid pipe LP4 on the first condenser 20A side. The on-off valve V12 is provided at the end of the liquid pipe LP5 on the second condenser 20B side. The on-off valve V13 is provided at the end of the liquid pipe LP6 on the liquid pipe LP8 side. The on-off valve V14 is provided at the end of the liquid pipe LP7 on the liquid pipe LP8 side. The on-off valve V15 is provided at the end of the liquid pipe LP10 on the first condenser 20A side. The on-off valve V16 is provided at the end of the liquid pipe LP11 on the second condenser 20B side.

A function of the on-off valve V will be described in detail in a description of the first passage setting, the second passage setting, the third passage setting, and the fourth passage setting to be described later.

The steam pipe SP and the liquid pipe LP will be described.

The steam pipe SP is a pipe for transporting a gas-phase coolant GP-COO. Aluminum, copper, or the like may be used as a material of the steam pipe SP.

As illustrated in FIG. 1, the steam pipe SP1, the steam pipe SP3, and the steam pipe SP4 connect the first evaporator 10A to the first condenser 20A. The steam pipe SP1, the steam pipe SP3, and the steam pipe SP5 connect the first evaporator 10A to the second condenser 20B. The steam pipe SP2, the steam pipe SP3, and the steam pipe SP4 connect the second evaporator 10B to the first condenser 20A. The steam pipe SP2, the steam pipe SP3, and the steam pipe SP5 connect the second evaporator 10B to the second condenser 20B.

As illustrated in FIG. 1, the steam pipe SP6 and the steam pipe SP8 connect the first evaporator 10A to the compressor 30. The steam pipe SP7 and the steam pipe SP8 connect the second evaporator 10B to the compressor 30. The steam pipe SP9 and the steam pipe SP10 connect the first condenser 20A to the compressor 30. The steam pipe SP9 and the steam pipe SP11 connect the second condenser 20B to the compressor 30.

Each of a connecting part of the steam pipe SP1, the steam pipe SP2, and the steam pipe SP3, a connecting part of the steam pipe SP3, the steam pipe SP4, and the steam pipe SP5, a connecting part of the steam pipe SP6, the steam pipe SP7, and the steam pipe SP8, and a connecting part of the steam pipe SP9, the steam pipe SP10, and the steam pipe SP11 makes the connection with a three-way joint (for example, an RT three-way ring tee from Asoh Co., Ltd.) or the like.

The liquid pipe LP is a pipe for transporting a liquid-phase coolant LP-COO. Aluminum, copper, or the like may be used as a material of the liquid pipe LP.

As illustrated in FIG. 1, the liquid pipe LP1, the liquid pipe LP3, and the liquid pipe LP4 connect the first evaporator 10A to the first condenser 20A. The liquid pipe LP1, the liquid pipe LP3, and the liquid pipe LP5 connect the first evaporator 10A to the second condenser 20B. The liquid pipe LP2, the liquid pipe LP3, and the liquid pipe LP4 connect the second evaporator 10B to the first condenser 20A. The liquid pipe LP2, the liquid pipe LP3, and the liquid pipe LP5 connect the second evaporator 10B to the second condenser 20B.

As illustrated in FIG. 1, the liquid pipe LP6 and the liquid pipe LP8 connect the first evaporator 10A to the expansion valve 40. The liquid pipe LP7 and the liquid pipe LP8 connect the second evaporator 10B to the expansion valve 40. The liquid pipe LP9 and the liquid pipe LP10 connect the first condenser 20A to the expansion valve 40. The liquid pipe LP9 and the liquid pipe LP11 connect the second condenser 20B to the expansion valve 40.

Each of a connecting part of the liquid pipe LP1, the liquid pipe LP2, and the liquid pipe LP3, a connecting part of the liquid pipe LP3, the liquid pipe LP4, and the liquid pipe LP5, a connecting part of the liquid pipe LP6, the liquid pipe LP7, and the liquid pipe LP8, and a connecting part of the liquid pipe LP9, the liquid pipe LP10, and the liquid pipe LP11 makes the connection with a three-way joint (for example, an RT three-way ring tee from Asoh Co., Ltd.) or the like.

The first evaporator 10A, the second evaporator 10B, the first condenser 20A, and the second condenser 20B have been described to be connected by the steam pipes SP1, SP2, SP3, SP4, and SP5, as illustrated in FIG. 1. Further, the first evaporator 10A, the second evaporator 10B, the first condenser 20A, and the second condenser 20B have been described to be connected by the liquid pipes LP1, LP2, LP3, LP4, and LP5.

On the other hand, the first evaporator 10A and the first condenser 20A may be connected by one steam pipe, and also the second evaporator 10B and the second condenser 20B may be connected by another steam pipe. In addition, the first evaporator 10A and the first condenser 20A may be connected by one liquid pipe, and also the second evaporator 10B and the second condenser 20B may be connected by another liquid pipe.

The steam pipe SP and the liquid pipe LP have been described above.

Next, the first passage setting, the second passage setting, the third passage setting, and the fourth passage setting will be described. A passage of a gas-phase coolant GP-COO from each of the first evaporator 10A and the second evaporator 10B to each of the first condenser 20A and the second condenser 20B, and a passage of a liquid-phase coolant LP-COO from each of the first condenser 20A and the second condenser 20B to each of the first evaporator 10A and the second evaporator 10B are set in each of the first passage setting, the second passage setting, the third passage setting, and the fourth passage setting.

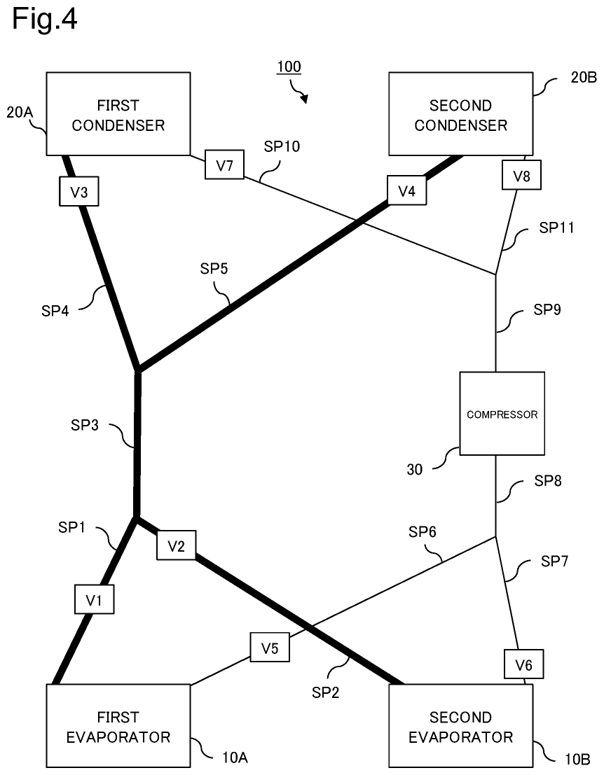

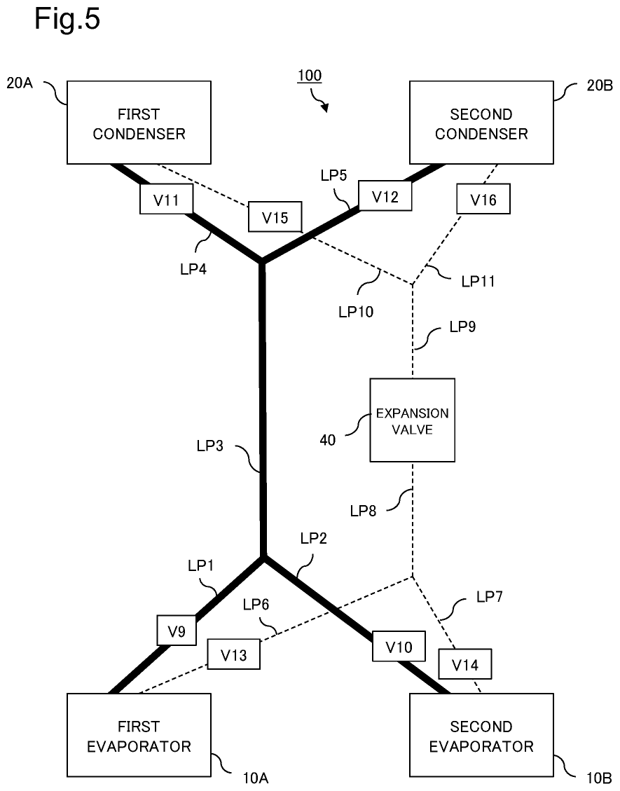

The first passage setting will be described. FIG. 4 and FIG. 5 are diagrams for illustrating the first passage setting. Specifically, FIG. 4 is a diagram illustrating a passage of a gas-phase coolant GP-COO in the first passage setting in a form of adding the passage to FIG. 2 with thick lines. FIG. 5 is a diagram illustrating a passage of a liquid-phase coolant LP-COO in the first passage setting in a form of adding the passage to FIG. 3 with thick lines.

The first passage setting causes gas-phase coolants GP-COO flowing out from the first evaporator 10A and the second evaporator 10B to flow into the first condenser 20A and the second condenser 20B without passing through the compressor 30. The first passage setting further causes liquid-phase coolants LP-COO flowing out from the first condenser 20A and the second condenser 20B to flow into the first evaporator 10A and the second evaporator 10B without passing through the expansion valve 40.

On-off states of the on-off valves V in the first passage setting will be described. In the first passage setting, the on-off valve V1, the on-off valve V2, the on-off valve V3, the on-off valve V4, the on-off valve V9, the on-off valve V10, the on-off valve V11, and the on-off valve V12 are opened. The on-off valve V5, the on-off valve V6, the on-off valve V7, the on-off valve V8, the on-off valve V13, the on-off valve V14, the on-off valve V15, and the on-off valve V16 are closed in the first passage setting.

A flow of a gas-phase coolant GP-COO in the first passage setting will be described. In the first passage setting, a gas-phase coolant GP-COO flowing out from each of the first evaporator 10A and the second evaporator 10B flows into the first condenser 20A and the second condenser 20B through a path indicated by thick lines in FIG. 4.

Specifically, a gas-phase coolant GP-COO flowing out from the first evaporator 10A passes through the steam pipe SP1 and the steam pipe SP3, then further passes through each of the steam pipe SP4 and the steam pipe SP5, and flows into each of the first condenser 20A and the second condenser 20B. A gas-phase coolant GP-COO flowing out from the second evaporator 10B passes through the steam pipe SP2 and the steam pipe SP3, then further passes through each of the steam pipe SP4 and the steam pipe SP5, and flows into each of the first condenser 20A and second condenser 20B.

A flow of a liquid-phase coolant LP-COO in the first passage setting will be described. In the first passage setting, a liquid-phase coolant GP-COO flowing out from each of the first condenser 20A and the second condenser 20B flows into the first evaporator 10A and the second evaporator 10B through a path indicated by thick lines in FIG. 5.

Specifically, a liquid-phase coolant LP-COO flowing out from the first condenser 20A passes through the liquid pipe LP4 and the liquid pipe LP3, then further passes through each of the liquid pipe LP1 and the liquid pipe LP2, and flows into each of the first evaporator 10A and the second evaporator 10B. A gas-phase coolant GP-COO flowing out from the second condenser 20B passes through the liquid pipe LP5 and the liquid pipe LP3, then further passes through each of the liquid pipe LP1 and the liquid pipe LP2, and flows into each of the first evaporator 10A and the second evaporator 10B. The first passage setting has been described above.

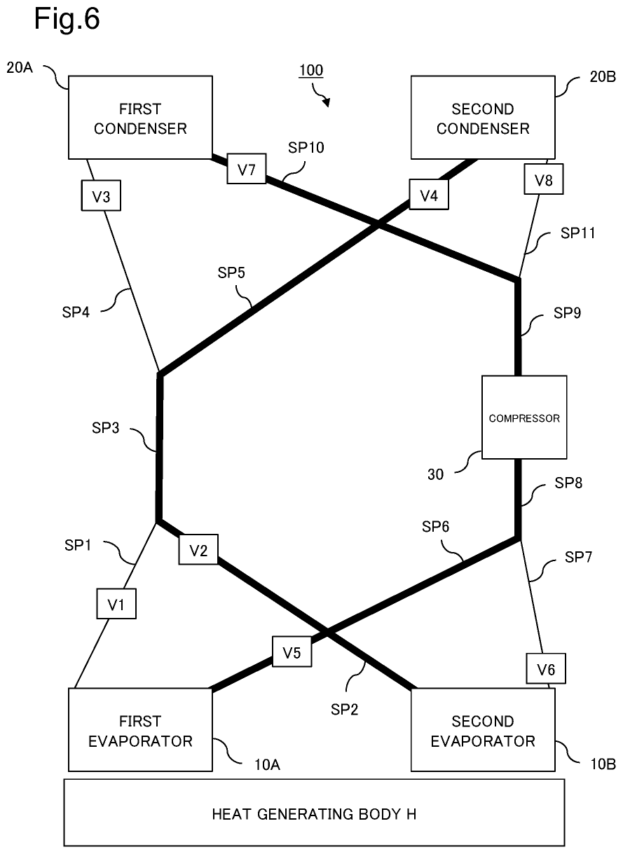

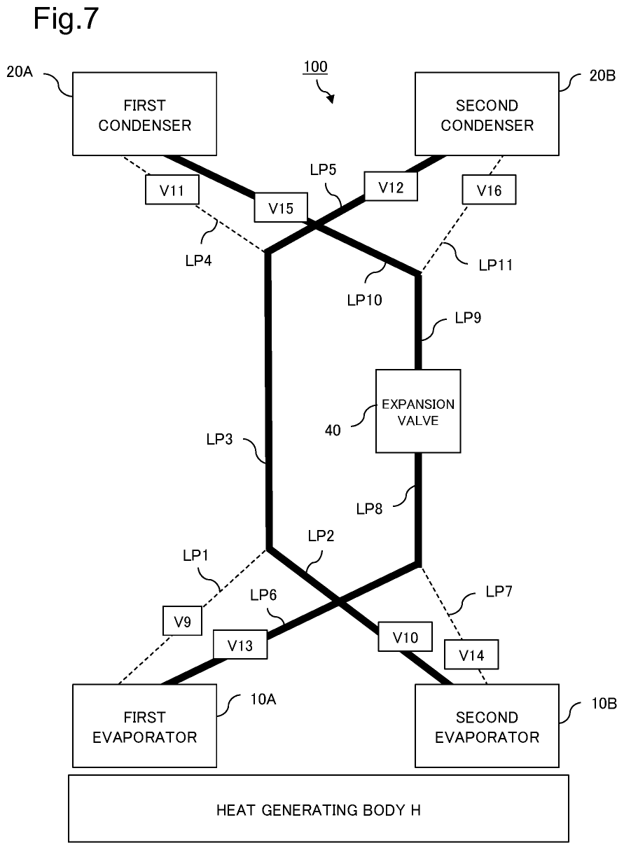

The second passage setting will be described. FIG. 6 and FIG. 7 are diagrams for illustrating the second passage setting. Specifically, FIG. 6 is a diagram illustrating a passage of a gas-phase coolant GP-COO in the second passage setting in a form of adding the passage to FIG. 2 with thick lines. FIG. 7 is a diagram illustrating a passage of a liquid-phase coolant LP-COO in the second passage setting in a form of adding the passage to FIG. 3 with thick lines.

The second passage setting causes a gas-phase coolant GP-COO flowing out from the first evaporator 10A to flow into the first condenser 20A through the compressor 30 and causes a liquid-phase coolant LP-COO flowing out from the first condenser 20A to flow into the first evaporator 10A through the expansion valve 40. The second passage setting further causes a gas-phase coolant GP-COO flowing out from the second evaporator 10B to flow into the second condenser 20B without passing through the compressor 30 and causes a liquid-phase coolant LP-COO flowing out from to the second condenser 20B to flow into the second evaporator 10B without passing through the expansion valve 40.

On-off states of the on-off valves V in the second passage setting will be described. In the second passage setting, the on-off valve V2, the on-off valve V4, the on-off valve V5, the on-off valve V7, the on-off valve V10, the on-off valve V12, the on-off valve V13, and the on-off valve V15 are opened. On the other hand, the on-off valve V1, the on-off valve V3, the on-off valve V6, the on-off valve V8, the on-off valve V9, the on-off valve V11, the on-off valve V14, and the on-off valve V16 are closed in the second passage setting.

A flow of a gas-phase coolant GP-COO in the second passage setting will be described. In the second passage setting, a gas-phase coolant GP-COO flowing out from each of the first evaporator 10A and the second evaporator 10B flows into each of the first condenser 20A and the second condenser 20B through a path indicated by thick lines in FIG. 6.

Specifically, a gas-phase coolant GP-COO flowing out from the first evaporator 10A passes through the steam pipe SP6, the steam pipe SP8, the compressor 30, the steam pipe SP9, and the steam pipe SP10, and then flows into the first condenser 20A. A gas-phase coolant GP-COO flowing out from the second evaporator 10B passes through the steam pipe SP2, the steam pipe SP3, and the steam pipe SP5, and then flows into the second condenser 20B.

A flow of a liquid-phase coolant LP-COO in the second passage setting will be described. In the second passage setting, a liquid-phase coolant GP-COO flowing out from each of the first condenser 20A and the second condenser 20 B flows into each of the first evaporator 10A and the second evaporator 10B through a path indicated by thick lines in FIG. 7.

Specifically, a liquid-phase coolant LP-COO flowing out from the first condenser 20A passes through the liquid pipe LP10, the liquid pipe LP9, the expansion valve 40, the liquid pipe LP8, and the liquid pipe LP6, and then flows into the first evaporator 10A. A liquid-phase coolant LP-COO flowing out from the second condenser 20B passes through the liquid pipe LP5, the liquid pipe LP3, and the liquid pipe LP2, and then flows into the second evaporator 10B. The second passage setting has been described above.

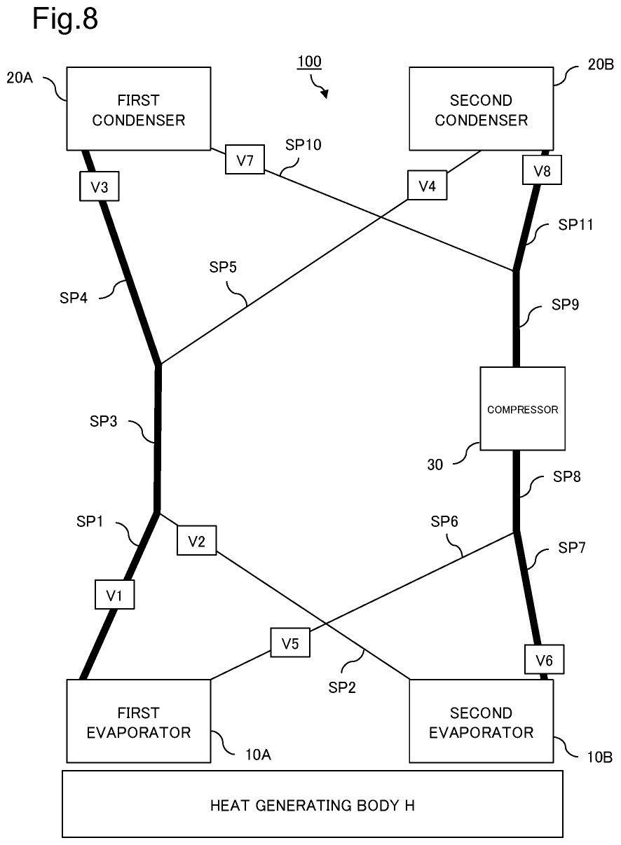

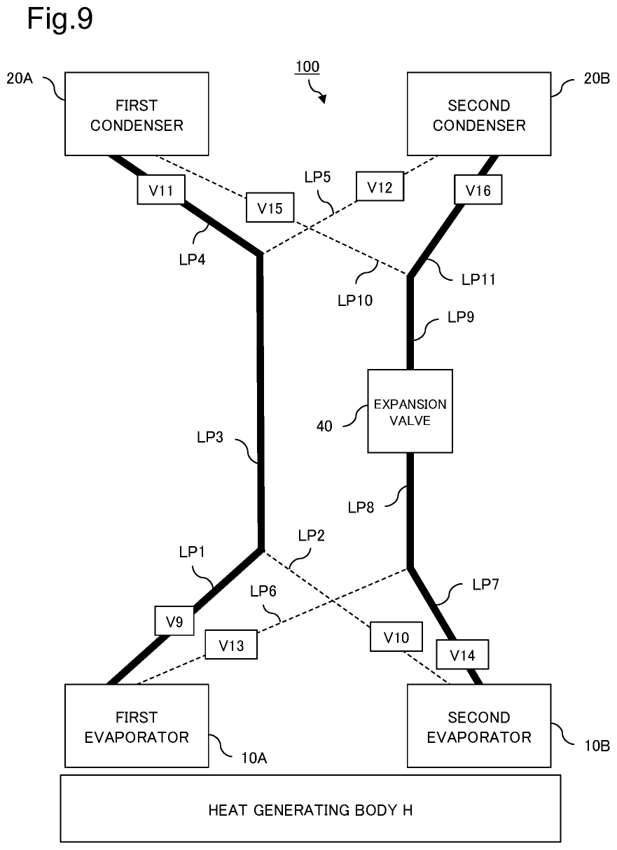

The third passage setting will be described. FIG. 8 and FIG. 9 are diagrams for illustrating the third passage setting. Specifically, FIG. 8 is a diagram illustrating a passage of a gas-phase coolant GP-COO in the third passage setting in a form of adding the passage to FIG. 2 with thick lines. FIG. 9 is a diagram illustrating a passage of a liquid-phase coolant LP-COO in the third passage setting in a form of adding the passage to FIG. 3 with thick lines.

The third passage setting causes a gas-phase coolant GP-COO flowing out from the first evaporator 10A to flow into the first condenser 20A without passing through the compressor 30 and causes a liquid-phase coolant LP-COO flowing out from the first condenser 20A to flow into the first evaporator 10A without passing through the expansion valve 40. The third passage setting further causes a gas-phase coolant GP-COO flowing out from the second evaporator 10B to flow into the second condenser 20B through the compressor 30 and causes a liquid-phase coolant LP-COO flowing out from the second condenser 20B to flow into the second evaporator 10B through the expansion valve 40.

On-off states of the on-off valves V in the third passage setting will be described. In the third passage setting, the on-off valve V1, the on-off valve V3, the on-off valve V6, the on-off valve V8, the on-off valve V9, the on-off valve V11, the on-off valve V14, and the on-off valve V16 are opened. On the other hand, the on-off valve V2, the on-off valve V4, the on-off valve V5, the on-off valve V7, the on-off valve V10, the on-off valve V12, the on-off valve V13, and the on-off valve V15 are closed in the third passage setting.

A flow of a gas-phase coolant GP-COO in the third passage setting will be described. In the third passage setting, a gas-phase coolant GP-COO flowing out from each of the first evaporator 10A and the second evaporator 10B flows into each of the first condenser 20A and the second condenser 20B through a path indicated by thick lines in FIG. 8.

Specifically, a gas-phase coolant GP-COO flowing out from the first evaporator 10A passes through the steam pipe SP1, the steam pipe SP3, and the steam pipe SP4, and then flows into the first condenser 20A. A gas-phase coolant GP-COO flowing out from the second evaporator 10B passes through the steam pipe SP7, the steam pipe SP8, the compressor 30, the steam pipe SP9, and the steam pipe SP11, and then flows into the second condenser 20B.

A flow of a liquid-phase coolant LP-COO in the third passage setting will be described. In the third passage setting, a liquid-phase coolant GP-COO flowing out from each of the first condenser 20A and the second condenser 20B flows into each of the first evaporator 10A and the second evaporator 10B through a path indicated by thick lines in FIG. 9.

Specifically, a liquid-phase coolant LP-COO flowing out from the first condenser 20A passes through the liquid pipe LP4, the liquid pipe LP3, and the liquid pipe LP1, and then flows into the first evaporator 10A. A liquid-phase coolant LP-COO flowing out from the second condenser 20B further passes through the liquid pipe LP11, the liquid pipe LP9, the expansion valve 40, the liquid pipe LP8, and the liquid pipe LP7, and then flows into the second evaporator 10B.

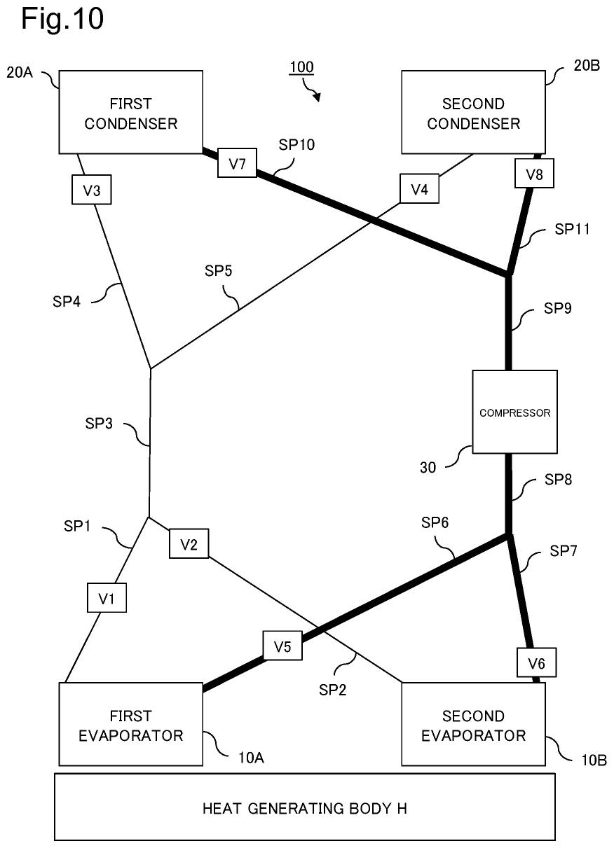

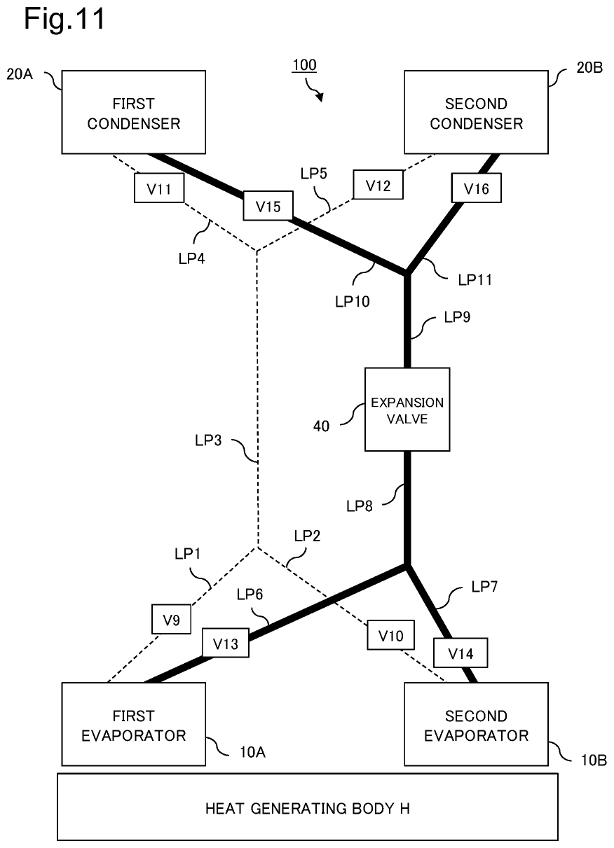

The fourth passage setting will be described. FIG. 10 and FIG. 11 are diagrams for illustrating the fourth passage setting. Specifically, FIG. 10 is a diagram illustrating a passage of a gas-phase coolant GP-COO in the fourth passage setting on FIG. 2 with thick lines. FIG. 11 is a diagram illustrating a passage of a liquid-phase coolant LP-COO in the fourth passage setting on FIG. 3 with thick lines.

The fourth passage setting causes a gas-phase coolants GP-COO flowing out from the first evaporator 10A and the second evaporator 10B to flow into the first condenser 20A and the second condenser 20B through the compressor 30. The fourth passage setting further causes liquid-phase coolants LP-COO flowing out from the first condenser 20A and the second condenser 20B to flow into the first evaporator 10A and the second evaporator 10B through the expansion valve 40.

On-off states of the on-off valves V in the fourth passage setting will be described. In the fourth passage setting, the on-off valve V5, the on-off valve V6, the on-off valve V7, the on-off valve V8, the on-off valve V13, the on-off valve V14, the on-off valve V15, and the on-off valve V16 are opened. On the other hand, the on-off valve V1, the on-off valve V2, the on-off valve V3, the on-off valve V4, the on-off valve V9, the on-off valve V10, the on-off valve V11, and the on-off valve V12 are closed in the fourth passage setting.

A flow of a gas-phase coolant GP-COO in the fourth passage setting will be described. In the fourth passage setting, a gas-phase coolant GP-COO flowing out from each of the first evaporator 10A and the second evaporator 10B flows into each of the first condenser 20A and the second condenser 20B through a path indicated by thick lines in FIG. 10.

Specifically, a gas-phase coolant GP-COO flowing out from the first evaporator 10A passes through the steam pipe SP6, the steam pipe SP8, the compressor 30, and the steam pipe SP9, then further passes through each of the steam pipe SP10 and the steam pipe SP11, and flows into each of the first condenser 20A and the second condenser 20B. A gas-phase coolant GP-COO flowing out from the second evaporator 10B passes through the steam pipe SP7, the steam pipe SP8, the compressor 30, and the steam pipe SP9, then further passes through each of the steam pipe SP10 and the steam pipe SP11, and flows into each of the first condenser 20A and the second condenser 20B.

A flow of a liquid-phase coolant LP-COO in the fourth passage setting will be described. In the fourth passage setting, a liquid-phase coolant LP-COO flowing out from each of the first condenser 20A and the second condenser 20B flows into each of the first evaporator 10A and the second evaporator 10B through a path indicated by thick lines in FIG. 11.

Specifically, a liquid-phase coolant LP-COO flowing out from the first condenser 20A passes through the liquid pipe LP10, the liquid pipe LP9, the expansion valve 40, and the liquid pipe LP8, then further passes through the liquid pipe LP6 and the liquid pipe LP7, and flows into each of the first evaporator 10A and the second evaporator 10B. A liquid-phase coolant LP-COO flowing out from the second condenser 20B passes through the liquid pipe LP11, the liquid pipe LP9, the expansion valve 40, and the liquid pipe LP8, then further passes through each of the liquid pipe LP6 and the liquid pipe LP7, and flows into each of the first evaporator 10A and the second evaporator 10B.

The configuration of the cooling device 100 has been described above.

Next, an operation of the cooling device 100 will be described.

It is assumed that one of the first passage setting, the second passage setting, the third passage setting, and the fourth passage setting is previously selected in the cooling device 100. First, when the heat-generating body H is started, the first evaporator 10A and the second evaporator 10B receives heat from the heat-generating body H. Consequently, the heat-generating body H is cooled. By the first evaporator 10A and the second evaporator 10B receiving heat from the heat-generating body H, a liquid-phase coolant LP-COO in each of the first evaporator 10A and the second evaporator 10B evaporates. By the evaporation, a gas-phase coolant GP-COO is generated in each of the first evaporator 10A and the second evaporator 10B.

The generated gas-phase coolant GP-COO flows into the first condenser 20A and the second condenser 20B in accordance with the content of the selected passage setting.

The gas-phase coolants GP-COO flowing into the first condenser 20A and the second condenser 20B radiate heat to the outside air through the first condenser 20A and the second condenser 20B. Consequently, the gas-phase coolants GP-COO condense. Liquid-phase coolants LP-COO generated by the condensation flow into the first evaporator 10A and the second evaporator 10B in accordance with the content of the selected passage setting and receive heat of the heat-generating body H again.

As described above, the coolant COO undergoes a phase change from the liquid phase to the gas phase in each of the first evaporator 10A and the second evaporator 10B by receiving heat of the heat-generating body H and flows into each of the first condenser 20A and the second condenser 20B. The coolant COO undergoes a phase change from the gas phase to the liquid phase in each of the first condenser 20A and the second condenser 20B by radiating heat to the air outside the server room and flows into each of the first evaporator 10A and the second evaporator 10B.

The operation of the cooling device 100 has been described above.

Next, a specific example of a configuration of each of the first evaporator 10A, the second evaporator 10B, the second condenser 20A, and the second condenser 20B will be described.

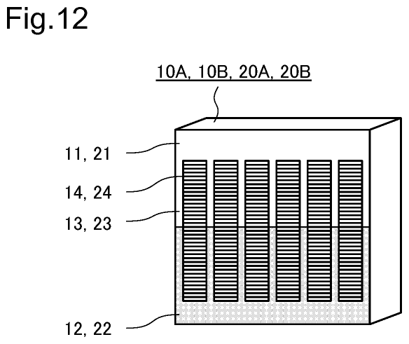

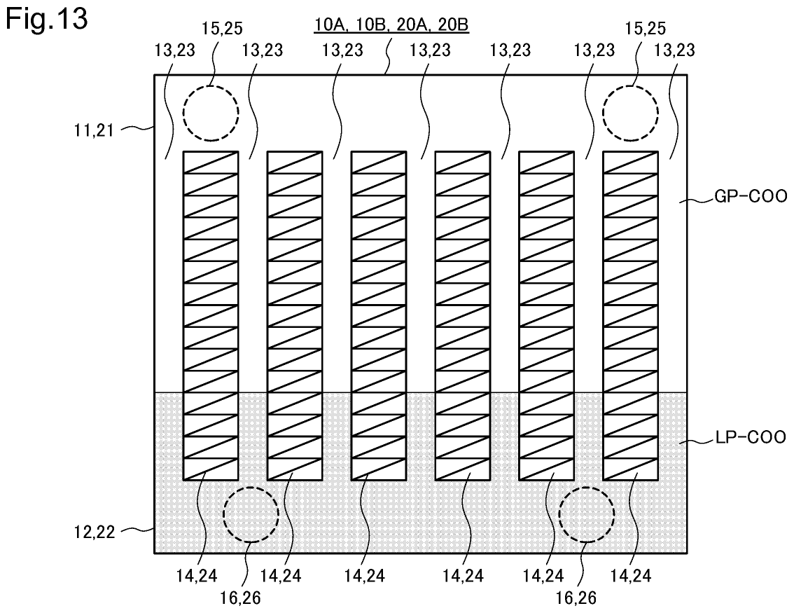

FIG. 12 is a perspective view illustrating a configuration of each of the first evaporator 10A, the second evaporator 10B, the first condenser 20A, and the second condenser 20B. Note that the steam pipes SP and the liquid pipes LP are omitted in FIG. 12. FIG. 13 is a transparent schematic diagram in which an internal configuration of each of the first evaporator 10A, the second evaporator 10B, the first condenser 20A, and the second condenser 20B is schematically seen through. Basic configurations of the first evaporator 10A, the second evaporator 10B, the first condenser 20A, and the second condenser 20B are the same.

For example, as illustrated in FIG. 12 and FIG. 13, each of the first evaporator 10A, the second evaporator 10B, the first condenser 20A, and the second condenser 20B is formed in a flat plate shape. As illustrated in FIG. 13, each of the first evaporator 10A, the second evaporator 10B, the first condenser 20A, and the second condenser 20B internally includes a cavity and stores a liquid-phase coolant LP-COO and a gas-phase coolant GP-COO.

As illustrated in FIG. 12 and FIG. 13, each of the first evaporator 10A and the second evaporator 10B is configured to include an upper tank part 11, a lower tank part 12, a plurality of connecting pipe parts 13, and a plurality of evaporator fin parts 14. Similarly, each of the first condenser 20A and the second condenser 20B is configured to include an upper tank part 21, a lower tank part 22, a plurality of connecting pipe parts 23, and a plurality of condenser fin parts 24. The upper tank part 11/21 is placed on the upper side of the lower tank part 12/22 in a vertical direction.

As illustrated in FIG. 13, two upper holes 15 and two lower holes 16 are respectively formed on the upper tank part 11 and the lower tank part 12 of each of the first evaporator 10A and the second evaporator 10B. Two upper holes 25 and two lower holes 26 are respectively formed on the upper tank part 21 and the lower tank part 22 of the first condenser 20A and the second condenser 20B.

Each connecting pipe part 13 in the first evaporator 10A and the second evaporator 10B connects the upper tank part 11 to the lower tank part 12. A plurality of the connecting pipe parts 13 are provided.

Each connecting pipe part 23 in the first condenser 20A and the second condenser 20B connects the upper tank part 21 to the lower tank part 22. A plurality of connecting pipe parts 23 are provided.

The evaporator fin parts 14 are provided between the connecting pipe parts 13. The evaporator fin parts 14 take away heat from the heat-generating body H and conduct the received heat to a liquid-phase coolant LP-COO in the connecting pipe parts 13. The liquid-phase coolant LP-COO receiving the heat undergoes a phase change to a gas-phase coolant GP-COO and rises in the connecting pipe parts 13.

The condenser fin parts 24 are provided between the connecting pipe parts 23, similarly to the evaporator fin parts 14. The condenser fin parts 24 radiate heat of a gas-phase coolant GP-COO flowing in from the upper tank part 21 to outside the cooling device 100. The gas-phase coolant GP-COO heat of which is radiated undergoes a phase change to a liquid-phase coolant LP-COO and falls in the connecting pipe parts 23 toward the lower tank part 22.

Each of the evaporator fin part 14 and the condenser fin part 24 includes a plurality of fins, and the plurality of fins are configured in such a way that the air passes between the fins. Specifically, in an evaporator fin part 14 region, the air can pass through each of the first evaporator 10A and the second evaporator 10B from one principal plane of the evaporator toward the other principal plane. Similarly, in a condenser fin part 24 region, the air can pass through each of the first condenser 20A and the second condenser 20B from one principal plane of the condenser toward the other principal plane.

The first evaporator 10A is connected to each of the steam pipe SP1 and the steam pipe SP6 through each of the two upper holes 15 and is also connected to each of the liquid pipe LP1 and the liquid pipe LP6 through each of the two lower holes 16. The second evaporator 10B is connected to each of the steam pipe SP2 and the steam pipe SP7 through each of the two upper holes 15 and is also connected to each of the liquid pipe LP2 and the liquid pipe LP7 through each of the two lower holes 16. The first condenser 20A is connected to each of the steam pipe SP4 and the steam pipe SP10 through each of the two upper holes 15 and is also connected to each of the liquid pipe LP4 and the liquid pipe LP10 through each of the two lower holes 16. The second condenser 20B is connected to each of the steam pipe SP5 and the steam pipe SP11 through each of the two upper holes 15 and is also connected to each of the liquid pipe LP5 and the liquid pipe LP11 through each of the two lower holes 16.

The specific example of the configuration of each of the first evaporator 10A, the second evaporator 10B, the second condenser 20A, and the second condenser 20B has been described above.

The first evaporator 10A and the second evaporator 10B have been described to be thermally connected to a single heat-generating body H in the description of the first evaporator 10A and the second evaporator 10B. The first evaporator 10A and the second evaporator 10B may be thermally connected to heat-generating bodies H different from each other, respectively.

The on-off valve V2, the on-off valve V4, the on-off valve V5, the on-off valve V7, the on-off valve V10, the on-off valve V12, the on-off valve V13, and the on-off valve V15 have been described to be opened, and also the on-off valve V1, the on-off valve V3, the on-off valve V6, the on-off valve V8, the on-off valve V9, the on-off valve V14, the on-off valve V11, and the on-off valve V16 have been described to be closed, in the description of the aforementioned second passage setting.

On the other hand, the on-off valve V2, the on-off valve V3, the on-off valve V5, the on-off valve V8, the on-off valve V10, the on-off valve V11, the on-off valve V13, and the on-off valve V16 may be opened, and also the on-off valve V1, the on-off valve V4, the on-off valve V6, the on-off valve V7, the on-off valve V9, the on-off valve V12, the on-off valve V14, and the on-off valve V15 may be closed, in the second passage setting.

In this case, the second passage setting causes a gas-phase coolant GP-COO flowing out from the first evaporator 10A to flow into the second condenser 20B through the compressor 30 and causes a liquid-phase coolant LP-COO flowing out from the second condenser 20B to flow into the first evaporator 10A through the expansion valve 40. The second passage setting in this case further causes a gas-phase coolant GP-COO flowing out from the second evaporator 10B to flow into the first condenser 20A without passing through the compressor 30 and causes a liquid-phase coolant LP-COO flowing out from the first condenser 20A to flow into the second evaporator 10B without passing through the expansion valve 40.

The on-off valve V1, the on-off valve V3, the on-off valve V6, the on-off valve V8, the on-off valve V9, the on-off valve V11, the on-off valve V14, and the on-off valve V16 have been described to be opened, and also the on-off valve V2, the on-off valve V4, the on-off valve V5, the on-off valve V7, the on-off valve V10, the on-off valve V12, the on-off valve V13, and the on-off valve V15 have been described to be closed, in the description of the third passage setting.

On the other hand, the on-off valve V1, the on-off valve V4, the on-off valve V6, the on-off valve V7, the on-off valve V9, the on-off valve V12, the on-off valve V14, and the on-off valve V15 may be opened, and also the on-off valve V2, the on-off valve V3, the on-off valve V5, the on-off valve V8, the on-off valve V10, the on-off valve V11, the on-off valve V13, and the on-off valve V16 may be closed, in the third passage setting.

In this case, the third passage setting causes a gas-phase coolant GP-COO flowing out from the first evaporator 10A to flow into the second condenser 20B without passing through the compressor 30 and causes a liquid-phase coolant LP-COO flowing out from the second condenser 20B to flow into the first evaporator 10A without passing through the expansion valve 40. The third passage setting in this case further causes a gas-phase coolant GP-COO flowing out from the second evaporator 10B to flow into the first condenser 20A through the compressor 30 and causes a liquid-phase coolant LP-COO flowing out from the first condenser 20A to flow into the second evaporator 10B through the expansion valve 40.

As described above, the cooling device 100 according to the first example embodiment of the present invention includes the first evaporator 10A, the second evaporator 10B, the first condenser 20A, the second condenser 20B, the compressor 30, and the expansion valve 40. The first evaporator 10A and the second evaporator 10B receive heat of the heat-generating body H, evaporate internally stored liquid-phase coolants LP-COO by the heat of the heat-generating body H, and cause gas-phase coolants GP-COO to flow out. The first condenser 20A and the second condenser 20B are connected to each of the first evaporator 10A and the second evaporator 10B. The first condenser 20A and the second condenser 20B condense a gas-phase coolant GP-COO flowing out from each of the first evaporator 10A and the second evaporator 10B and cause a liquid-phase coolant LP-COO to flow out to each of the first evaporator 10A and the second evaporator 10B. The compressor 30 is connected to the first evaporator 10A, the second evaporator 10B, the first condenser 20A, and the second condenser 20B. The compressor 30 compresses gas-phase coolants GP-COO flowing out from the first evaporator 10A and the second evaporator 10B. The expansion valve 40 is connected to the first evaporator 10A, the second evaporator 10B, the first condenser 20A, and the second condenser 20B.

The cooling device 100 is provided with one of the first passage setting, the second passage setting or the third passage setting, and the fourth passage setting in a selectable manner.

The first passage setting causes gas-phase coolants GP-COO flowing out from the first evaporator 10A and the second evaporator 10B to flow into the first condenser 20A and the second condenser 20B without passing through the compressor 30. The first passage setting further causes liquid-phase coolants LP-COO flowing out from the first condenser 20A and the second condenser 20B to flow into the first evaporator 10A and the second evaporator 10B without passing through the expansion valve 40.

The second passage setting causes a gas-phase coolant GP-COO flowing out from the first evaporator 10A to flow into one of the first condenser 20A and the second condenser 20B through the compressor 30 and causes a liquid-phase coolant LP-COO flowing out from the one of the first condenser 20A and the second condenser 20B to flow into the first evaporator 10A through the expansion valve 40. The second passage setting further causes a gas-phase coolant GP-COO flowing out from the second evaporator 10B to flow into the other of the first condenser 20A and the second condenser 20B without passing through the compressor 30 and causes a liquid-phase coolant LP-COO flowing out from the other of the first condenser 20A and the second condenser 20B to flow into the second evaporator 10B without passing through the expansion valve 40.

The third passage setting causes a gas-phase coolant GP-COO flowing out from the first evaporator 10A to flow into one of the first condenser 20A and the second condenser 20B without passing through the compressor 30 and causes a liquid-phase coolant LP-COO flowing out from the one of the first condenser 20A and the second condenser 20B to flow into the first evaporator 10A without passing through the expansion valve 40. The third passage setting further causes a gas-phase coolant GP-COO flowing out from the second evaporator 10B to flow into the other of the first condenser 20A and the second condenser 20B through the compressor 30 and causes a liquid-phase coolant LP-COO flowing out from the other of the first condenser 20A and the second condenser 20B to flow into the second evaporator 10B through the expansion valve 40.

The fourth passage setting causes gas-phase coolants GP-COO flowing out from the first evaporator 10A and the second evaporator 10B to flow into the first condenser 20A and the second condenser 20B through the compressor 30. The fourth passage setting further causes liquid-phase coolants LP-COO flowing out from the first condenser 20A and the second condenser 20B to flow into the first evaporator 10A and the second evaporator 10B through the expansion valve 40.

Thus, the cooling device 100 is provided with a setting using only a system (natural circulation cycle) circulating a coolant COO without use of the compressor 30 and the expansion valve 40 (the first passage setting), a setting using the natural circulation cycle with a system (compression refrigeration cycle) circulating a coolant by use of the compressor 30 and the expansion valve 40 (the second passage setting or the third passage setting), and a setting using only the compression refrigeration cycle (fourth passage setting) in a selectable manner. Furthermore, in the first passage setting, the second passage setting, the third passage setting, and the fourth passage setting, heat received by the first evaporator 10A and the second evaporator 10B is directly radiated to outside the cooling device 100 from the first condenser 20A and the second condenser 20B. Consequently, the cooling device 100 can cool the heat-generating body H with a simple configuration.

In the natural circulation cycle in the technology described in PTL 1, a coolant is circulated between the first evaporator and the first condenser. On the other hand, in the compression refrigeration cycle, a coolant is circulated between the third evaporator and the second condenser, and in addition, heat exchange is performed between the second condenser and the second evaporator in the heat exchanger, and a coolant is further circulated between the second evaporator and the first condenser. Thus, there is a problem that the configuration of the compression refrigeration cycle includes a more number of parts and is complex compared with the configuration of the natural circulation cycle, due to inclusion of the heat exchanger including the second condenser and the second evaporator. On the other hand, in the cooling device 100, heat received by the first evaporator 10A and the second evaporator 10B is radiated to outside the cooling device 100 from the first condenser 20A and the second condenser 20B without use of a heat exchanger including a second condenser and a second evaporator as is the case with the technology described in PTL 1. Consequently, the cooling device 100 can cool the heat-generating body H with a simple configuration.

### Second Example Embodiment

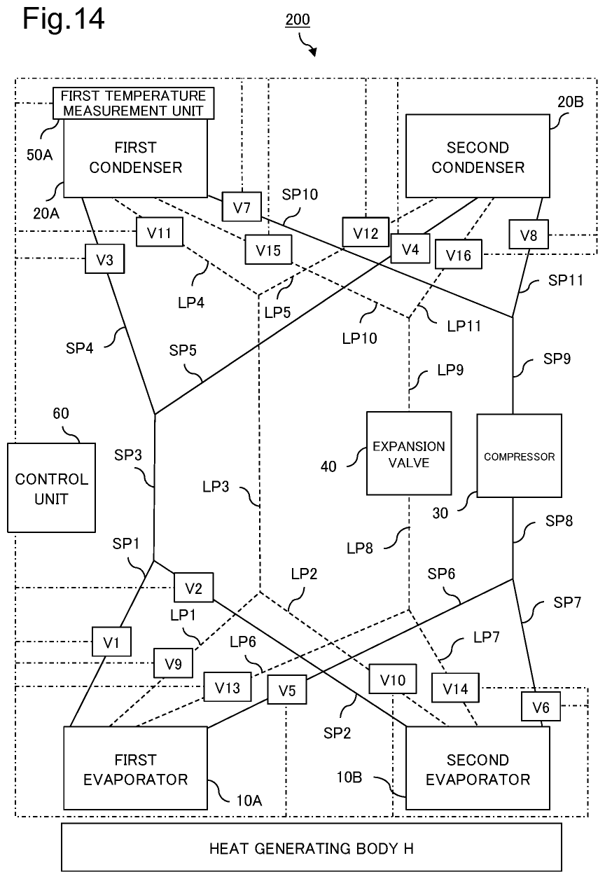

Next, a cooling device 200 according to a second example embodiment of the present invention will be described. FIG. 14 is a schematic diagram illustrating a configuration of the cooling device 200.

As illustrated in FIG. 14, the cooling device 200 includes a first evaporator 10A, a second evaporator 10B, a first condenser 20A, a second condenser 20B, a compressor 30, an expansion valve 40, a first temperature measurement unit 50A, and a control unit 60.

The cooling device 200 further includes on-off valves V1 to V16, steam pipes SP1 to SP11, and liquid pipes LP1 to LP11, as illustrated in FIG. 14.

The cooling device 100 and the cooling device 200 will be compared by use of FIG. 1 and FIG. 14. The cooling device 200 matches the cooling device 100 in including the first evaporator 10A, the second evaporator 10B, the first condenser 20A, the second condenser 20B, the compressor 30, the expansion valve 40, the on-off valves V1 to V16, the steam pipes SP1 to SP11, and the liquid pipes LP1 to LP11. On the other hand, the cooling device 200 differs from the cooling device 100 in further including the first temperature measurement unit 50A and the control unit 60.

The first temperature measurement unit 50A will be described. The first temperature measurement unit 50A is installed around a surface of the first condenser 20A. For example, when the first condenser 20A is cooled by wind sent from a fan or the like, the first temperature measurement unit 50A is installed around a surface against which the wind is blown, out of surfaces of the first condenser 20A. Further, as illustrated in FIG. 14, the first temperature measurement unit 50A is electrically connected to the control unit 60 to be described later. A common temperature sensor may be used as the first temperature measurement unit 50A.

The first temperature measurement unit 50A measures the temperature (hereinafter referred to as a “first temperature” as needed) of the air around the first condenser 20A. The first temperature measurement unit 50A outputs a measured value to the control unit 60 to be described later.

The control unit 60 will be described. As illustrated in FIG. 14, the control unit 60 is electrically connected to the first temperature measurement unit 50A and each of the on-off valves V1 to V16. The control unit 60 is further electrically connected to an unillustrated memory. It is assumed that the unillustrated memory previously stores a first threshold value and a second threshold value. It is further assumed that the second threshold value is greater than the first threshold value.

The control unit 60 selects one of the aforementioned first passage setting, the second passage setting, the third passage setting, and the fourth passage setting, based on the first temperature output from the first temperature measurement unit 50A. It is assumed that which of the second passage setting and the third passage setting is selected by the control unit 60 when the first temperature output from the first temperature measurement unit 50A exceeds the first threshold value and also is equal to or less than the second threshold value is previously determined. Selection of a passage setting by the control unit 60 will be described in detail in a description of an operation to be described later.

The control unit 60 further causes a gas-phase coolant GP-COO flowing out from each of the first evaporator 10A and the second evaporator 10B to flow into the first condenser 20A and the second condenser 20B, based on a content of a selected passage setting. The control unit 60 further causes a liquid-phase coolant LP-COO flowing out from each of the first condenser 20A and the second condenser 20B to flow into the first condenser 20A and the second condenser 20B, based on the content of the selected passage setting.

The configuration of the cooling device 200 has been described above.

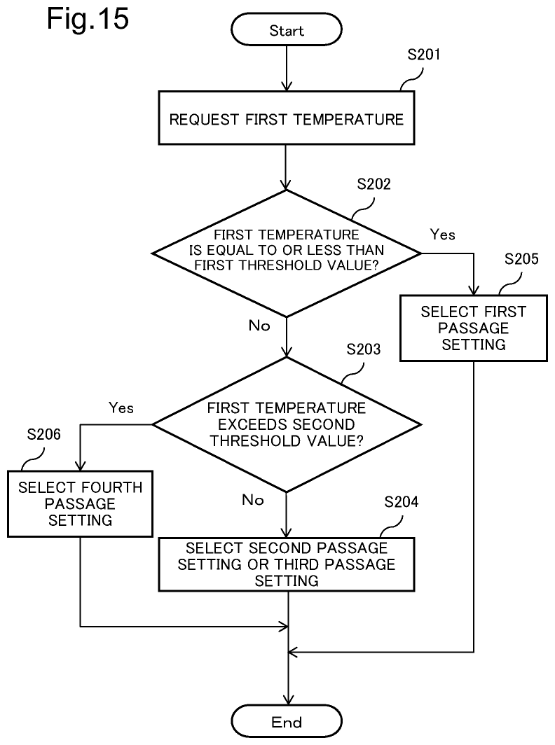

Next, a basic operation of the cooling device 200 will be described. FIG. 15 is a diagram illustrating an operation flow of the cooling device 200. The operation of the cooling device 200 is similar to the operation of the cooling device 100. On the other hand, the cooling device 200 differs from the cooling device 100 in that the control unit 60 selects one of the first passage setting, the second passage setting, the third passage setting, and the fourth passage setting, based on the first temperature output by the first temperature measurement unit 50A.

The selection of a passage setting by the control unit 60 will be described. For example, it is assumed in the following description that 25° C. is preset as the first threshold value. For example, it is further assumed that 35° C. is preset as the second threshold value. It is further assumed that the first temperature measurement unit 50A always measures the temperature (first temperature) of the air around the first condenser 20A.

First, the control unit 60 requests the first temperature from the first temperature measurement unit 50A (S201). Then, the first temperature measurement unit 50A outputs the first temperature measured in accordance with the request from the control unit 60 to the control unit 60.

The control unit 60 determines whether the first temperature is equal to or less than the first threshold value (S202). When 25° C. is preset as the first threshold value as described above, the control unit 60 determines whether the first temperature output from the first temperature measurement unit 50A is equal to or less than 25° C.

When the first temperature is determined to be equal to or less than the first threshold value (Yes in S202), the control unit 60 selects the first passage setting (S205). When the processing in S205 ends, the control unit 60 ends the selection of a passage setting.

When the first temperature is not determined to be equal to or less than the first threshold value (No in S202), the control unit 60 determines whether the first temperature exceeds the second threshold value (S203). When 35° C. is preset as the second threshold value as described above, the control unit 60 determines whether the first temperature exceeds 35° C.

When the first temperature is determined to exceed the second threshold value (Yes in S203), the control unit 60 selects the fourth passage setting (S206). When the processing in S206 ends, the control unit 60 ends the selection of a passage setting.

When the first temperature is not determined to exceed the second threshold value (No in S203), the control unit 60 selects the second passage setting or the third passage setting (S204). In the processing in S204, the control unit 60 selects the preset setting out of the second passage setting and the third passage setting. When the processing in S204 ends, the control unit 60 ends the selection of a passage setting.

The control unit 60 performs the processing in S201 when a predetermined time elapses after the selection of a passage setting is ended. The predetermined time here may be freely determined (for example, several minutes to several hours). The predetermined time may be determined according to the temperature of the air around the first condenser 20A. In this case, for example, when the temperature of the air around the first condenser 20A (the first temperature being a measured value by the first temperature measurement unit 50A) changes from the previous measured value by a predetermined temperature or more (for example, 10° C. or more), a time between the previous measurement time and the current measurement time may be re-set as the predetermined time.

The operation of the cooling device 200 has been described above.

In the description above, the first temperature measurement unit 50A has been described to be installed on a surface of the first condenser 20A. On the other hand, the first temperature measurement unit 50A may be installed on a surface of the second condenser 20B. In this case, the temperature of the air around the second condenser 20B is determined to be the first temperature.

The first temperature measurement unit 50A may be installed on both a surface of the first condenser 20A and a surface of the second condenser 20B. In this case, the first temperature measurement unit 50A installed on the surface of the first condenser 20A measures the temperature of the air around the first condenser 20A and outputs the measured temperature to the control unit 60. The first temperature measurement unit 50A installed on the surface of the second condenser 20B measures the temperature of the air around the second condenser 20B and outputs the measured temperature to the control unit 60. In this case, the control unit 60 determines the average value of the measured values output from the two first temperature measurement units 50A to be the first temperature.

The first temperature measurement unit 50A is not an indispensable configuration in the cooling device 200. When not including the first temperature measurement unit 50A, the cooling device 200 acquires the first temperature by an unillustrated communication means or the like.

As described above, the cooling device 200 according to the second example embodiment of the present invention further includes the control unit 60. The control unit 60 selects one of the first passage setting, the second passage setting, the third passage setting, and the fourth passage setting. The control unit 60 selects one of the first passage setting, the second passage setting, the third passage setting, and the fourth passage setting, based on the first temperature being the temperature of the air close to at least one of the first condenser 20A and the second condenser 20B. Based on the content of the selected setting, the control unit 60 causes a gas-phase coolant GP-COO flowing out from each of the first evaporator 10A and the second evaporator 10B to flow into each of the first condenser 20A and the second condenser 20B and causes a liquid-phase coolant LP-COO flowing out from each of the first condenser 20A and the second condenser 20B to flow into each of the first evaporator 10A and the second evaporator 10B.

Thus, the cooling device 200 selects one of the first passage setting, the second passage setting, the third passage setting, and the fourth passage setting, based on the temperature (first temperature) of the air close to at least one of the first condenser 20A and the second condenser 20B. Consequently, for example, by selecting the fourth passage setting by the control unit 60 when the first temperature is high, gas-phase coolants GP-COO flowing out from both the first evaporator 10A and the second evaporator 10B can be caused to flow into the first condenser 20A and the second condenser 20B through the compressor 30. Accordingly, the temperature of the gas-phase coolants GP-COO flowing into the first condenser 20A and the second condenser 20B can be raised according to a rise of the first temperature. Consequently, the temperature of the gas-phase coolants GP-COO flowing into the first condenser 20A and the second condenser 20B becoming lower than the first temperature can be suppressed. Consequently, the gas-phase coolants GP-COO flowing into the first condenser 20A and the second condenser 20B can stably radiate heat of the heat-generating body H to the air around the first condenser 20A and the second condenser 20B, in the cooling device 200. Accordingly, the cooling device 200 can stably cool the heat-generating body H.

Further, in a control method according to the present invention, the cooling device 200 includes the first evaporator 10A, the second evaporator 10B, the first condenser 20A, the second condenser 20B, the compressor 30, and the expansion valve 40. The first evaporator 10A and the second evaporator 10B receive heat of the heat-generating body H, evaporate internally stored liquid-phase coolants LP-COO by the heat of the heat-generating body H, and cause gas-phase coolants GP-COO to flow out. The first condenser 20A and the second condenser 20B are connected to each of the first evaporator 10A and the second evaporator 10B. The first condenser 20A and the second condenser 20B condense a gas-phase coolant GP-COO flowing out from each of the first evaporator 10A and the second evaporator 10B and cause a liquid-phase coolant LP-COO to flow out to each of the first evaporator 10A and the second evaporator 10B. The compressor 30 is connected to the first evaporator 10A, the second evaporator 10B, the first condenser 20A, and the second condenser 20B. The compressor 30 compresses gas-phase coolants GP-COO flowing out from the first evaporator 10A and the second evaporator 10B. The expansion valve 40 is connected to the first evaporator 10A, the second evaporator 10B, the first condenser 20A, and the second condenser 20B.

The cooling device 200 is selectably provided with the first passage setting, the second passage setting or the third passage setting, and the fourth passage setting.

The first passage setting causes gas-phase coolants GP-COO flowing out from the first evaporator 10A and the second evaporator 10B to flow into the first condenser 20A and the second condenser 20B without passing through the compressor 30. The first passage setting further causes liquid-phase coolants LP-COO flowing out from the first condenser 20A and the second condenser 20B to flow into the first evaporator 10A and the second evaporator 10B without passing through the expansion valve 40.

The second passage setting causes a gas-phase coolant GP-COO flowing out from the first evaporator 10A to flow into one of the first condenser 20A and the second condenser 20B through the compressor 30 and causes a liquid-phase coolant LP-COO flowing out from the one of the first condenser 20A and the second condenser 20B to flow into the first evaporator 10A through the expansion valve 40. The second passage setting further causes a gas-phase coolant GP-COO flowing out from the second evaporator 10B to flow into the other of the first condenser 20A and the second condenser 20B without passing through the compressor 30 and causes a liquid-phase coolant LP-COO flowing out from the other of the first condenser 20A and the second condenser 20B to flow into the second evaporator 10B without passing through the expansion valve 40.

The third passage setting causes a gas-phase coolant GP-COO flowing out from the first evaporator 10A to flow into one of the first condenser 20A and the second condenser 20B without passing through the compressor 30 and causes a liquid-phase coolant LP-COO flowing out from the one of the first condenser 20A and the second condenser 20B to flow into the first evaporator 10A without passing through the expansion valve 40. The third passage setting further causes a gas-phase coolant GP-COO flowing out from the second evaporator 10B to flow into the other of the first condenser 20A and the second condenser 20B through the compressor 30 and causes a liquid-phase coolant LP-COO flowing out from the other of the first condenser 20A and the second condenser 20B to flow into the second evaporator 10B through the expansion valve 40.

The fourth passage setting causes gas-phase coolants GP-COO flowing out from the first evaporator 10A and the second evaporator 10B to flow into the first condenser 20A and the second condenser 20B through the compressor 30. The fourth passage setting further causes liquid-phase coolants LP-COO flowing out from the first condenser 20A and the second condenser 20B to flow into the first evaporator 10A and the second evaporator 10B through the expansion valve 40.

The cooling device 200 in the control method according to the present invention further includes the control unit 60. The control unit 60 selects one of the first passage setting, the second passage setting, the third passage setting, and the fourth passage setting.

The control method according to the present invention selects one of the first passage setting, the second passage setting, the third passage setting, and the fourth passage setting, based on the first temperature being the temperature of the air close to at least one of the first condenser 20A and the second condenser 20B. Based on the content of the selected setting, the control method according to the present invention causes a gas-phase coolant GP-COO flowing out from each of the first evaporator 10A and the second evaporator 10B to flow into each of the first condenser 20A and the second condenser 20B and causes a liquid-phase coolant LP-COO flowing out from each of the first condenser 20A and the second condenser 20B to flow into each of the first evaporator 10A and the second evaporator 10B.

An effect of the control method according to the present invention is similar to the effect of the cooling device 200.

A control program according to the present invention causes a computer to execute processing similar to that by the aforementioned control method. An effect of the control method according to the present invention is similar to the effect of the cooling device 200.

A storage medium according to the present invention stores the aforementioned control program. An effect of the storage medium according to the present invention is similar to the effect of the cooling device 200.

As described above, the control unit 60 in the cooling device 200 according to the second example embodiment of the present invention selects the first passage setting when the first temperature is equal to or less than the first threshold value. The control unit 60 selects the fourth passage setting when the first temperature exceeds the second threshold value greater than the first threshold value. The control unit 60 selects the second passage setting or the third passage setting when the first temperature exceeds the first threshold value and also is equal to or less than the second threshold value. Based on the content of the selected setting, the control unit 60 causes a gas-phase coolant flowing out from each of the first evaporator and the second evaporator to flow into each of the first condenser and the second condenser and causes a liquid-phase coolant LP-COO flowing out from each of the first condenser 20A and the second condenser 20B to flow into each of the first evaporator 10A and the second evaporator 10B.

Thus, the control unit 60 selects the first passage setting when the first temperature is equal to or less than the first threshold value. The control unit 60 selects the fourth passage setting when the first temperature exceeds the second threshold value greater than the first threshold value. The control unit 60 selects the second passage setting or the third passage setting when the first temperature exceeds the first threshold value and also is equal to or less than the second threshold value. Consequently, the cooling device 200 does not use the compressor 30 when the first temperature is equal to or less than the first threshold value. The cooling device 200 compresses gas-phase coolants GP-COO flowing out from both the first evaporator 10A and the second evaporator 10B by use of the compressor 30 when the first temperature exceeds the second threshold value. The control unit 60 compresses a gas-phase coolant flowing out from one of the first evaporator 10A and the second evaporator 10B by use of the compressor 30 when the first temperature exceeds the first threshold value and also is equal to or less than the second threshold value. Thus, the cooling device 300 can decrease an amount of a gas-phase coolant GP-COO compressed by the compressor 30 as the first temperature lowers. Consequently, the cooling device 300 can decrease an amount of electric power used for the compressor 30 to compress a gas-phase coolant GP-COO.

### Third Example Embodiment

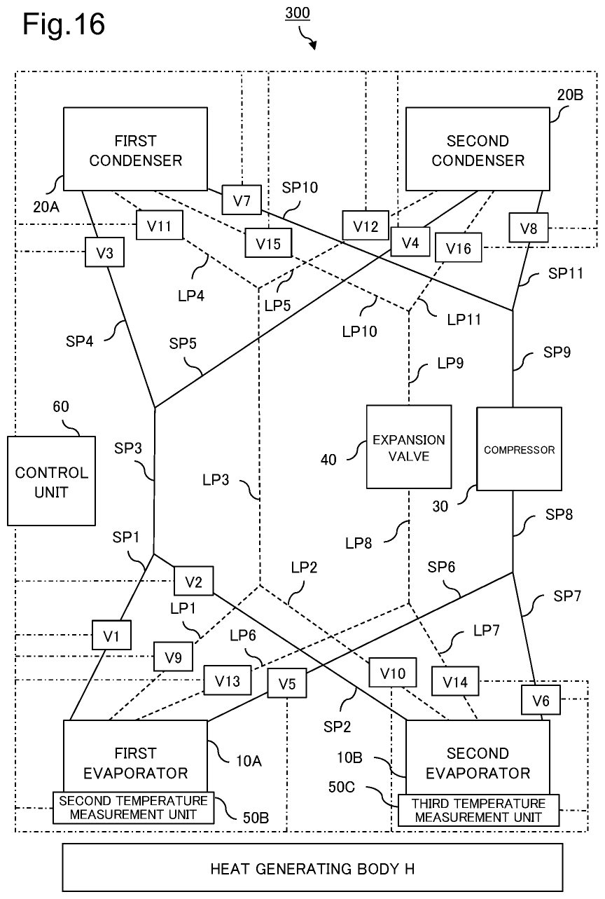

Next, a cooling device 300 according to a third example embodiment of the present invention will be described. FIG. 16 is a schematic diagram illustrating a configuration of the cooling device 300.

As illustrated in FIG. 16, the cooling device 300 includes a first evaporator 10A, a second evaporator 10B, a first condenser 20A, a second condenser 20B, a compressor 30, an expansion valve 40, a second temperature measurement unit 50B, a third temperature measurement unit 50C, and a control unit 60. The cooling device 300 further includes on-off valves V1 to V16, steam pipes SP1 to SP1, and liquid pipes LP1 to LP11, as illustrated in FIG. 16.

The cooling device 100 and the cooling device 300 will be compared by use of FIG. 1 and FIG. 16. The cooling device 300 matches the cooling device 100 in including the first evaporator 10A, the second evaporator 10B, the first condenser 20A, the second condenser 20B, the compressor 30, the expansion valve 40, the on-off valve V1 to the on-off valve V16, the steam pipe SP1 to the steam pipe SP11, and the liquid pipe LP1 to the liquid pipe LP11. On the other hand, the cooling device 300 differs from the cooling device 100 in further including the second temperature measurement unit 50B, the third temperature measurement unit 50C, and the control unit 60.

The second temperature measurement unit 50B will be described. The second temperature measurement unit 50B is installed around a surface of the first evaporator 10A. For example, the second temperature measurement unit 50B is installed around a surface facing a heat-generating body H out of surfaces of the first evaporator 10A. The second temperature measurement unit 50B is electrically connected to the control unit 60 to be described later, as illustrated in FIG. 16. A common temperature sensor may be used as the second temperature measurement unit 50B.

The second temperature measurement unit 50B measures the temperature (hereinafter referred to as a “second temperature” as needed) of the air around the first evaporator 10A. The second temperature measurement unit 50B outputs the measured second temperature to the control unit 60 to be described later.

The third temperature measurement unit 50C will be described. The third temperature measurement unit 50C is installed around a surface of the second evaporator 10B. For example, the third temperature measurement unit 50C is installed around a surface facing the heat-generating body H out of surfaces of the second evaporator 10B. The third temperature measurement unit 50C is electrically connected to the control unit 60 to be described later, as illustrated in FIG. 16. A common temperature sensor may be used as the third temperature measurement unit 50C.

The third temperature measurement unit 50C measures the temperature (hereinafter referred to as a “third temperature” as needed) of the air around the second evaporator 10B. The third temperature measurement unit 50C outputs the measured third temperature to the control unit 60 to be described later.

The control unit 60 will be described. As illustrated in FIG. 16, the control unit 60 is electrically connected to the second temperature measurement unit 50B, the third temperature measurement unit 50C, and each of the on-off valve V1 to the on-off valve V16. The control unit 60 is further electrically connected to an unillustrated memory. It is assumed that the unillustrated memory previously stores a third threshold value and a fourth threshold value. It is further assumed that the fourth threshold value is greater than the third threshold value.

The control unit 60 according to the second example embodiment has been described to select one of the first passage setting, the second passage setting, the third passage setting, and the fourth passage setting, based on the temperature (first temperature) of the air close to at least one of the first condenser and the second condenser. On the other hand, the control unit 60 according to the present example embodiment selects one of the aforementioned first passage setting, second passage setting, third passage setting, and fourth passage setting, based on the second temperature and the third temperature, to be described later, instead of the aforementioned first temperature.

Selection of a passage setting by the control unit 60 will be described in detail in a description of an operation to be described later.

Based on the content of the selected passage setting, the control unit 60 causes a gas-phase coolant GP-COO flowing out from each of the first evaporator 10A and the second evaporator 10B to flow into the first condenser 20A and the second condenser 20B. The control unit 60 further causes a liquid-phase coolant LP-COO flowing out from each of the first condenser 20A and the second condenser 20B to flow into each of the first evaporator 10A and the second evaporator 10B.

The second temperature measurement unit 50B and the third temperature measurement unit 50C are not indispensable configurations in the cooling device 200. When not including the second temperature measurement unit 50B and the third temperature measurement unit 50C, the cooling device 200 acquires the second temperature and the third temperature by an unillustrated communication means or the like.

The configuration of the cooling device 300 has been described above.

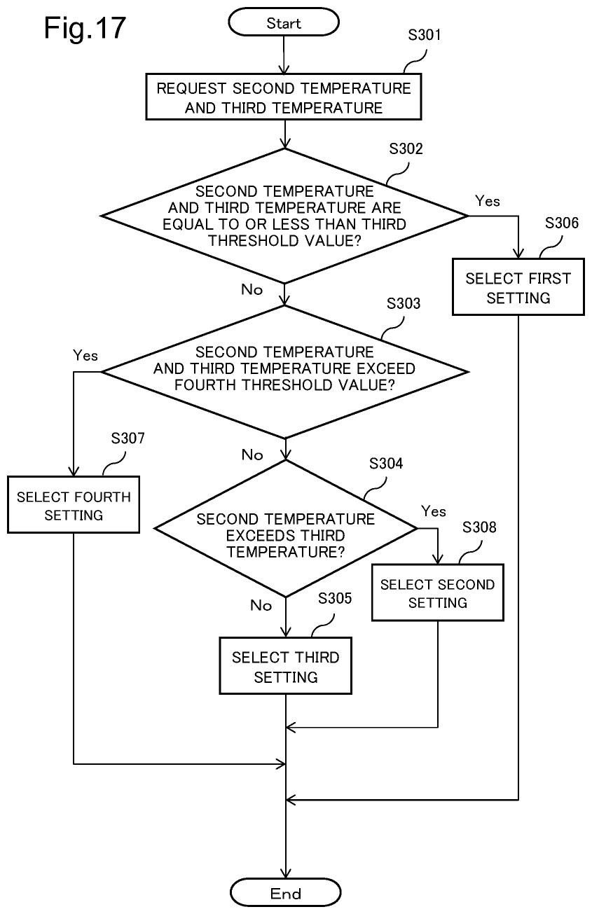

Next, an operation of the cooling device 300 will be described. FIG. 17 is a diagram illustrating an operation flow of the cooling device 300. The operation of the cooling device 300 is basically similar to the operation of the cooling device 100. On the other hand, the cooling device 300 differs from the cooling device 100 in that the control unit 60 selects one of the first passage setting, the second passage setting, the third passage setting, and the fourth passage setting, based on each of a measured value by the second temperature measurement unit 50B and a measured value by the third temperature measurement unit 50C.

The selection of a passage setting by the control unit 60 will be described. For example, it is assumed in the description below that 30° C. is preset as the third threshold value. For example, it is further assumed that 40° C. is preset as the fourth threshold value. It is further assumed that the second temperature measurement unit 50B always measures the temperature (second temperature) of the air around the first evaporator 10A. It is assumed that the third temperature measurement unit 50C always measures the temperature (third temperature) of the air around the second evaporator 10B.

First, the control unit 60 requests the second temperature from the second temperature measurement unit 50B and also requests the third temperature from the third temperature measurement unit 50C (S301). Then, the second temperature measurement unit 50B outputs the measured second temperature to the control unit 60 in accordance with the request from the control unit 60. The third temperature measurement unit 50C outputs the measured third temperature to the control unit 60 in accordance with the request from the control unit 60.

The control unit 60 determines whether both the second temperature and the third temperature are equal to or less than the third threshold value (S302). When 30° C. is preset as the third threshold value as described above, the control unit 60 determines whether both the second temperature and the third temperature are equal to or less than 30° C.

When both the second temperature and the third temperature are determined to be equal to or less than the third threshold value (Yes in S302), the control unit 60 selects the first passage setting (S306). When the processing in S306 ends, the control unit 60 ends the selection of a passage setting.

When not both the second temperature and the third temperature are determined to be equal to or less than the third threshold value (No in S302), the control unit 60 determines whether both the second temperature and the third temperature exceed the fourth threshold value (S303). When 40° C. is preset as the fourth threshold value as described above, the control unit 60 determines whether the measured value output by the first temperature measurement unit 50A exceeds 40° C.

When both the second temperature and the third temperature are determined to exceed the fourth threshold value (Yes in S303), the control unit 60 selects the fourth passage setting (S307). When the processing in S307 ends, the control unit 60 ends the selection of a passage setting.

When not both the second temperature and the third temperature are determined to exceed the fourth threshold value (No in S303), the control unit 60 determines whether the second temperature exceeds the third temperature (S304).

When the second temperature is determined to exceed the third temperature (Yes in S304), the control unit 60 selects the second passage setting (S308). When the processing in S308 ends, the control unit 60 ends the selection of a passage setting.

On the other hand, when the second temperature is not determined to exceed the third temperature (No in S304), the control unit 60 selects the third passage setting (S305). When the processing in S305 ends, the control unit 60 ends the selection of a passage setting.

The control unit 60 performs the processing in S301 when a predetermined time elapses after the selection of a passage setting is ended. The predetermined time here may be freely determined (for example, several minutes to several hours). The predetermined time may be determined according to a temperature change of the heat-generating body H. In this case, for example, a cycle of temperature changes of the heat-generating body H may be previously measured, and the predetermined time may be determined based on the measurement result of the cycle.

The operation of the cooling device 300 has been described above.

As described above, the cooling device 300 according to the third example embodiment of the present invention further includes the control unit 60. The control unit 60 selects one of the first passage setting, the second passage setting, the third passage setting, and the fourth passage setting, based on the second temperature being the temperature of the air around the first evaporator 10A and the third temperature being the temperature of the air around the second evaporator 10B instead of the first temperature. Based on the content of the selected setting, the control unit 60 causes a gas-phase coolant GP-COO flowing out from each of the first evaporator 10A and the second evaporator 10B to flow into each of the first condenser 20A and the second condenser 20B and causes a liquid-phase coolant LP-COO flowing out from each of the first condenser 20A and the second condenser 20B to flow into each of the first evaporator 10A and the second evaporator 10B.

Thus, the control unit 60 selects one of the first passage setting, the second passage setting, the third passage setting, and the fourth passage setting, based on the second temperature and the third temperature instead of the first temperature. Consequently, for example, when the second temperature is higher than the third temperature, the second passage setting may be selected. Consequently, in the cooling device 300, a gas-phase coolant GP-COO flowing out from the first evaporator 10A (one of the first evaporator 10A and the second evaporator 10B the temperature of the air around which is higher compared with the other) flows into the first condenser 20B or the second condenser 20A with the temperature raised by the compressor 30. Consequently, the gas-phase coolant GP-COO flowing out from the first evaporator 10A can radiate a more amount of heat in the first condenser 20B or the second condenser 20A compared with a case of the temperature not being raised by the compressor 30. Consequently, the cooling device 300 can stably cool the heat-generating body H.

Further, as described above, the control unit 60 in the cooling device 300 according to the third example embodiment of the present invention selects the second passage setting when the second temperature is higher than the third temperature. When the third temperature is lower than the third heat generation temperature, the control unit 60 selects the third passage setting. When at least one of the second temperature and the third temperature is not less than the third threshold value and also not greater than the fourth threshold value, and the second temperature is higher than the third temperature, the control unit 60 selects the second passage setting. When at least one of the second temperature and the third temperature is not less than the third threshold value and not greater than the fourth threshold value, and the third temperature is higher than the second temperature, the control unit 60 selects the third passage setting. Based on the content of the selected setting, the control unit 60 causes a gas-phase coolant GP-COO flowing out from each of the first evaporator 10A and the second evaporator 10B to flow into each of the first condenser 20A and the second condenser 20B and causes a liquid-phase coolant LP-COO flowing out from each of the first condenser 20A and the second condenser 20B to flow into each of the first evaporator 10A and the second evaporator 10B.

Thus, the control unit 60 selects the second passage setting when the second temperature is higher than the third temperature. The control unit 60 selects the third passage setting when the third temperature is lower than the third heat generation temperature. The control unit 60 selects the first passage setting when each of the second temperature and the third temperature is less than the third threshold value. The control unit 60 selects the fourth passage setting when each of the second temperature and the third temperature is greater than the fourth threshold value greater than the third threshold value. Consequently, even when the temperatures of the air close to the first evaporator 10A and the second evaporator 10B are different, the heat-generating body H can be efficiently cooled.

Specifically, in the cooling device 300, a gas-phase coolant GP-COO flowing out from the first evaporator 10A (one of the first evaporator 10A and the second evaporator 10B the temperature of the air around which is higher compared with the other) flows into the first condenser 20B or the second condenser 20A with the temperature raised by the compressor 30. Consequently, the gas-phase coolant GP-COO flowing out from the first evaporator 10A can radiate a more amount of heat in the first condenser 20B or the second condenser 20A compared with a case of the temperature not being raised by the compressor 30.

Further, when the temperature of the air around each of the first evaporator 10A and the second evaporator 10B is low (when the second temperature and the third temperature are less than the third threshold value), the compressor 30 is not used. Consequently, consumption of power required for the compressor 30 to compress a gas-phase coolant GP-COO can be held down. When the temperature of the air around each of the first evaporator 10A and the second evaporator 10B is high (when the second temperature and the third temperature are greater than the fourth threshold value), gas-phase coolants GP-COO flowing out from both the first evaporator 10A and the second evaporator 10B flow into the first condenser 20B or the second condenser 20A with the temperature raised by the compressor 30. Consequently, the gas-phase coolant GP-COO flowing out from the first evaporator 10A can radiate a more amount of heat in the first condenser 20B or the second condenser 20A compared with a case of the temperature not being raised by the compressor 30. Consequently, the cooling device 300 can stably cool the heat-generating body H.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2018-010422, filed on Jan. 25, 2018, the disclosure of which is incorporated herein in its entirety by reference.

### REFERENCE SIGNS LIST

10A First evaporator
10B Second evaporator
20A First condenser
20B Second condenser
11, 21 Upper tank part
12, 22 Lower tank part
13, 23 Connecting pipe part
14, 24 Evaporator fin part
15, 25 Upper hole
16, 26 Lower hole
30 Compressor
40 Expansion valve
50A First temperature measurement unit
50B Second temperature measurement unit
50C Third temperature measurement unit
60 Control unit
100, 200, 300 Cooling device

What is claimed is:

1. A cooling device comprising:
a first evaporator and a second evaporator each of which receiving heat of a heat-generating body, configured to evaporate an internally stored liquid-phase coolant by heat of the heat-generating body, and cause a gas-phase coolant to flow out;
a first condenser and a second condenser being connected to each of the first evaporator and the second evaporator, configured to condense a gas-phase coolant flowing out from each of the first evaporator and the second evaporator, and cause a liquid-phase coolant to flow out to each of the first evaporator and the second evaporator;
a compressor being connected to the first evaporator, the second evaporator, the first condenser, and the second condenser, and configured to compress a gas-phase coolant flowing out from the first evaporator and the second evaporator; and
an expansion valve being connected to the first evaporator, the second evaporator, the first condenser, and the second condenser, and configured to expand a liquid-phase coolant flowing out from the first condenser and the second condenser, wherein,
one of a first passage setting, a second passage setting or a third passage setting, and a fourth passage setting is provided in a selectable manner,
the first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve,
the second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve,
the third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and
the fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve.

2. The cooling device according to claim 1, further comprising
a controller configured to select one of the first passage setting, the second passage setting, the third passage setting, and the fourth passage setting, wherein
the controller
selects one of the first passage setting, the second passage setting, the third passage setting, and the fourth passage setting, based on a first temperature being a temperature of air close to at least one of the first condenser and the second condenser, and,
based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

3. The cooling device according to claim 2, wherein
the controller
selects the first passage setting when the first temperature is equal to or less than a first threshold value,
selects the fourth passage setting when the first temperature exceeds a second threshold value greater than the first threshold value,
selects the second passage setting or the third passage setting when the first temperature exceeds the first threshold value and also is equal to or less than the second threshold value, and,
based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

4. The cooling device according to claim 2, wherein
the controller
selects one of the first passage setting, the second passage setting, the third passage setting, and the fourth passage setting, based on, instead of the first temperature, a second temperature being a temperature of air around the first evaporator and a third temperature being a temperature of air around the second evaporator, and,
based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

5. The cooling device according to claim 4, wherein
the controller
selects the first passage setting when each of the second temperature and the third temperature is less than a third threshold value,
selects the fourth passage setting when each of the second temperature and the third temperature is greater than a fourth threshold value greater than the third threshold value,
selects the second passage setting when at least one of the second temperature and the third temperature is not less than the third threshold value and also not greater than the fourth threshold value, and the second temperature is higher than the third temperature,
selects the third passage setting when at least one of the second temperature and the third temperature is not less than the third threshold value and also not greater than the fourth threshold value, and the third temperature is higher than the second temperature, and,
based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

6. A control method comprising
controlling a cooling device including:
a first evaporator and a second evaporator each of which receiving heat of a heat-generating body, configured to evaporate an internally stored liquid-phase coolant by heat of the heat-generating body, and cause a gas-phase coolant to flow out;
a first condenser and a second condenser being connected to each of the first evaporator and the second evaporator, configured to condense a gas-phase coolant flowing out from each of the first evaporator and the second evaporator, and cause a liquid-phase coolant to flow out to each of the first evaporator and the second evaporator;
a compressor being connected to the first evaporator, the second evaporator, the first condenser, and the second condenser, and configured to compress a gas-phase coolant flowing out from the first evaporator and the second evaporator;
an expansion valve being connected to the first evaporator, the second evaporator, the first condenser, and the second condenser, and configured to expand a liquid-phase coolant flowing out from the first condenser and the second condenser; and
a controller, wherein
the controller
can select one of
a first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve,
a second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve,
a third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and
a fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve,
selects one of the first passage setting, the second passage setting, the third passage setting, and the fourth passage setting, based on a first temperature being a temperature of air close to at least one of the first condenser and the second condenser, and,
based on a content of a selected setting, causes a gas-phase coolant flowing out from each of the first evaporator and the second evaporator to flow into each of the first condenser and the second condenser and causes a liquid-phase coolant flowing out from each of the first condenser and the second condenser to flow into each of the first evaporator and the second evaporator.

7. A storage medium storing a control program for controlling a cooling device including:
a first evaporator and a second evaporator each of which receiving heat of a heat-generating body, configured to evaporate an internally stored liquid-phase coolant by heat of the heat-generating body, and cause a gas-phase coolant to flow out;
a first condenser and a second condenser being connected to each of the first evaporator and the second evaporator, configured to condense a gas-phase coolant flowing out from each of the first evaporator and the second evaporator, and cause a liquid-phase coolant to flow out to each of the first evaporator and the second evaporator;
a compressor being connected to the first evaporator, the second evaporator, the first condenser, and the second condenser, and configured to compress a gas-phase coolant flowing out from the first evaporator and the second evaporator;
an expansion valve being connected to the first evaporator, the second evaporator, the first condenser, and the second condenser, and configured to expand a liquid-phase coolant flowing out from the first condenser and the second condenser; and
a controller,
the control program configured to cause a computer to execute processing of causing the controller to
be able to select one of
a first passage setting causing gas-phase coolants flowing out from the first evaporator and the second evaporator to flow into the first condenser and the second condenser without passing through the compressor and causing liquid-phase coolants flowing out from the first condenser and the second condenser to flow into the first evaporator and the second evaporator without passing through the expansion valve,
a second passage setting causing a gas-phase coolant flowing out from the first evaporator to flow into one of the first condenser and the second condenser through the compressor and causing a liquid-phase coolant flowing out from one of the first condenser and the second condenser to flow into the first evaporator through the expansion valve, and also causing a gas-phase coolant flowing out from the second evaporator to flow into another of the first condenser and the second condenser without passing through the compressor and causing a liquid-phase coolant flowing out from another of the first condenser and the second condenser to flow into the second evaporator without passing through the expansion valve,
a third passage setting causing a gas-phase coolant flowing out from the first evaporator to flow into one of the first condenser and the second condenser without passing through the compressor and causing a liquid-phase coolant flowing out from one of the first condenser and the second condenser to flow into the first evaporator without passing through the expansion valve, and also causing a gas-phase coolant flowing out from the second evaporator to flow into another of the first condenser and the second condenser through the compressor and causing a liquid-phase coolant flowing out from another of the first condenser and the second condenser to flow into the second evaporator through the expansion valve, and
a fourth passage setting causing gas-phase coolants flowing out from the first evaporator and the second evaporator to flow into the first condenser and the second condenser through the compressor and causing liquid-phase coolants flowing out from the first condenser and the second condenser to flow into the first evaporator and the second evaporator through the expansion valve,
select one of the first passage setting, the second passage setting, the third passage setting, and the fourth passage setting, based on a first temperature being a temperature of air close to at least one of the first condenser and the second condenser, and,
based on a content of a selected setting, cause a gas-phase coolant flowing out from each of the first evaporator and the second evaporator to flow into each of the first condenser and the second condenser and cause a liquid-phase coolant flowing out from each of the first condenser and the second condenser to flow into each of the first evaporator and the second evaporator.
